(19) United States
(12) Patent Application Publication
(10) Pub. No.: US 2026/0052941 A1
(43) Pub. Date: Feb. 19, 2026

(54) SUBSTRATE PROCESSING WITH REDUCTION OF PRESSURE AND HYDRATION BEFORE DEVELOPMENT

(71) Applicant: Tokyo Electron Limited, Tokyo (JP)

(72) Inventors: Soichiro OKADA, Leuven (BE); Ken ANDO, Leuven (BE); Hiroki TADATOMO, Tokyo (JP); Arnaud Alain Jean DAUENDORFFER, Kumamoto (JP)

(21) Appl. No.: 19/250,059

(22) Filed: Jun. 26, 2025

(30) Foreign Application Priority Data
Jul. 5, 2024 (JP) 2024-109206
Jan. 7, 2025 (JP) 2025-002457

(51) Int. Cl. H01L 21/677; H01L 21/033; H01L 21/67

(52) U.S. Cl. CPC H01L 21/67739; H01L 21/0331; H01L 21/0337; H01L 21/67023

(57) ABSTRACT

A substrate processing method includes: forming a photosensitive film on a surface of a substrate; accommodating the substrate with the formed photosensitive film in a first chamber and exposing the photosensitive film to exposure light in the first chamber; accommodating the substrate with the formed photosensitive film in a second chamber different from the first chamber and performing a pressure reduction process to reduce pressure inside the second chamber to a subatmospheric pressure; subjecting, after the pressure reduction process, the photosensitive film to a moisture-containing gas; and developing the photosensitive film of the substrate after exposing and subjecting.

### CROSS-REFERENCE TO RELATED APPLICATIONS

This application is based upon and claims the benefit of priority from Japanese Patent Application No. 2025-002457, filed on Jan. 7, 2025, and Japanese Patent Application No. 2024-109206, filed on Jul. 5, 2024, the entire contents of which are incorporated herein by reference.

### BACKGROUND

### Field

The present disclosure relates to a substrate processing method, a substrate processing apparatus, a substrate processing system, and a program.

### Description of the Related Art

Japanese Unexamined Patent Publication No. 2024-7375 discloses a substrate transfer method in which a wafer is sequentially transferred to an exposure apparatus, a heating module, and a development module, and the time from unloading from the exposure apparatus to transfer to the heating module is kept substantially constant.

### SUMMARY

Disclosed herein is a substrate processing method. The substrate processing method may include: forming a photosensitive film on a surface of a substrate; accommodating the substrate with the formed photosensitive film in a first chamber and exposing the photosensitive film to exposure light in the first chamber; accommodating the substrate with the formed photosensitive film in a second chamber different from the first chamber and performing a pressure reduction process to reduce pressure inside the second chamber to a subatmospheric pressure; subjecting, after the pressure reduction process, the photosensitive film to a moisture-containing gas; and developing the photosensitive film of the substrate after said exposing and said subjecting.

Additionally, a substrate processing apparatus is disclosed herein. The substrate processing apparatus may include: a chamber isolated from an exposure chamber, wherein a substrate is accommodated in the exposure chamber for an exposure process for a photosensitive film formed on a surface of the substrate; a pressure reduction apparatus configured to reduce pressure inside the chamber to a subatmospheric pressure; a hydration apparatus configured to subject the photosensitive film to a moisture-containing gas; a transfer apparatus configured to transfer the substrate; and circuitry configured to: control the transfer apparatus so as to load the substrate into the chamber after the exposure process for the photosensitive film to the exposure light and before a development process on the photosensitive film; control the pressure reduction apparatus so as to reduce the pressure inside the chamber to the subatmospheric pressure after the substrate is loaded into the chamber and before the substrate is unloaded from the chamber; and control the hydration apparatus so as to subject the photosensitive film to the moisture-containing gas after the pressure inside the chamber is reduced to the subatmospheric pressure and before the development process on the photosensitive film.

Additionally, a non-transitory memory device having instructions stored thereon is disclosed herein. The instructions cause, in response to execution by a processing device, the processing device to control a substrate processing apparatus to: form a photosensitive film on a surface of a substrate; accommodate the substrate with the formed photosensitive film in a first chamber and expose the photosensitive film to exposure light in the first chamber; accommodate the substrate with the formed photosensitive film in a second chamber different from the first chamber and perform pressure reduction process to reduce pressure inside the second chamber to a subatmospheric pressure; subject, after the pressure reduction process, the photosensitive film to a moisture-containing gas; and develop the photosensitive film of the substrate after exposing the photosensitive film to the exposure light and subjecting the photosensitive film to the moisture-containing gas.

### BRIEF DESCRIPTION OF THE DRAWINGS

FIG. 1 is a plan view schematically illustrating an example configuration of a wafer processing system.

FIG. 2 is a front view of the wafer processing system illustrated in FIG. 1.

FIG. 3 is a schematic diagram illustrating an example wafer processing system including an exposure apparatus.

FIG. 4 is a schematic diagram illustrating an example pressure reduction and hydration system.

FIG. 5 is a schematic diagram illustrating a modification of the pressure reduction and hydration system.

FIG. 6 illustrates an example operation of the pressure reduction apparatus in FIG. 5.

FIG. 7 is a block diagram illustrating an example functional configuration of a control apparatus.

FIG. 8 is a schematic diagram illustrating an example state of the photosensitive film near the exposure site.

FIGS. 9A, 9B, 9C, 9D, and 9E are schematic diagrams illustrating example state changes of the photosensitive film up to the wet-type development process.

FIGS. 10A, 10B, 10C, 10D, 10E, 10F, and 10G are schematic diagrams illustrating example state changes of the photosensitive film up to the dry-type development process.

FIG. 11 is a block diagram illustrating an example hardware configuration of the control apparatus.

FIG. 12 is a diagram illustrating a modification of the wafer processing system.

FIG. 13 is a diagram illustrating another modification of the wafer processing system.

FIG. 14 is a diagram illustrating yet another modification of the wafer processing system.

FIG. 15 is a diagram illustrating yet another modification of the wafer processing system.

FIG. 16 is a flowchart illustrating an example substrate processing procedure.

FIG. 17 is a flowchart illustrating an example substrate processing procedure.

FIG. 18 is a graph illustrating an example of effect confirmation.

FIG. 19 is a graph illustrating an example of effect confirmation.

FIG. 20 is a graph illustrating an example of effect confirmation.

FIG. 21 is a graph illustrating an example of effect confirmation.

FIG. 22 is a graph illustrating an example of effect confirmation.

FIG. 23 is a graph illustrating an example of effect confirmation.

FIG. 24 is a block diagram illustrating a modification of the wafer processing system.

FIG. 25 is a flowchart illustrating a modification of the substrate processing procedure.

FIG. 26 is a graph illustrating an example of effect confirmation for the modification.

### DETAILED DESCRIPTION

In the following description, with reference to the drawings, the same reference numbers are assigned to the same components or to similar components having the same function, and overlapping description is omitted.

The wafer processing system as a substrate processing apparatus will be described with reference to the drawings. Elements having substantially the same functional configuration are denoted by the same reference numerals, and redundant explanations are omitted.

### Wafer Processing System

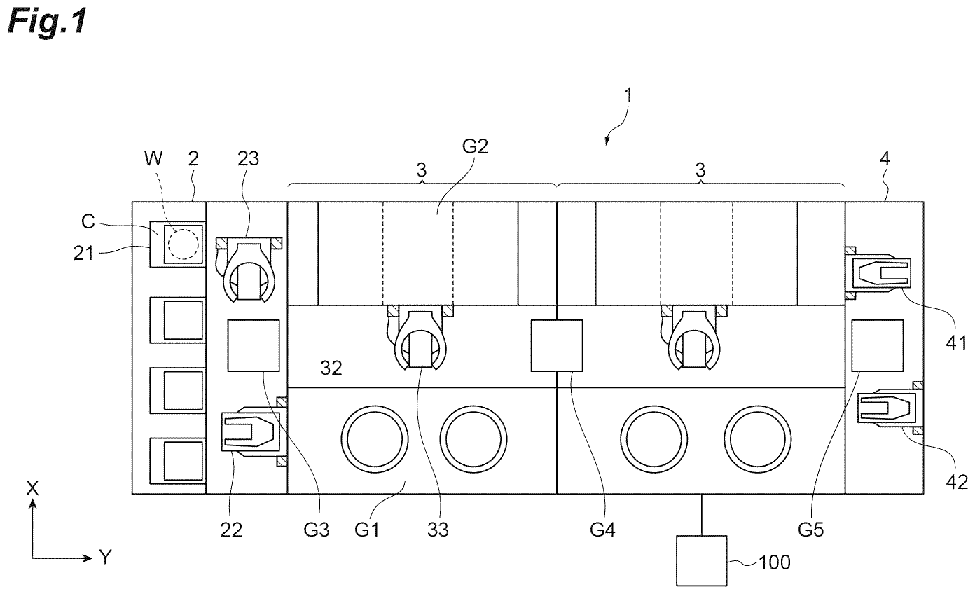

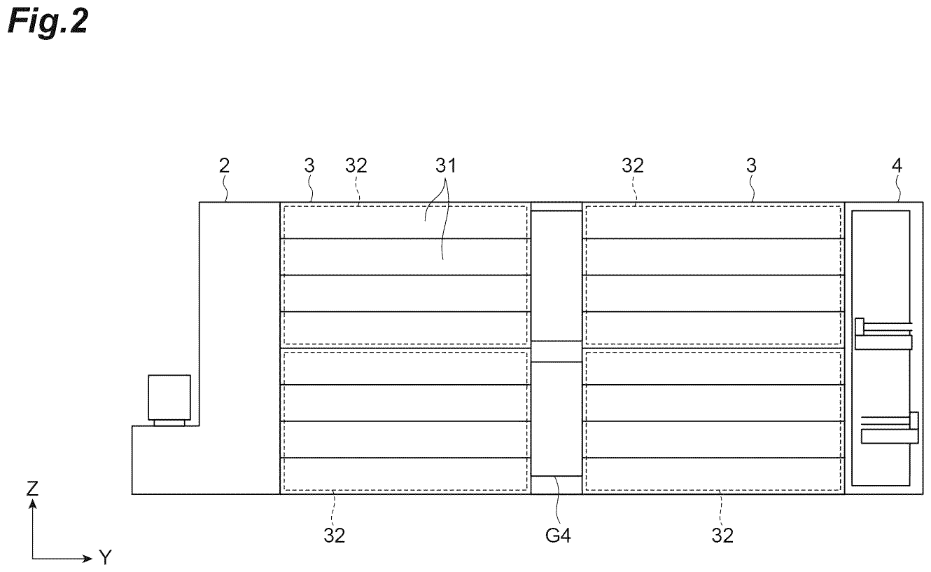

First, the configuration of the wafer processing system will be described. FIGS. 1 and 2 are plan and front views, respectively, schematically illustrating the configuration of a wafer processing system 1. The example wafer processing system 1 is described as an example of a photolithography processing system that performs a resist film formation process and a development process on a wafer W.

As illustrated in FIG. 1, the wafer processing system 1 includes a cassette station 2 where cassettes C, each housing multiple wafers W, are loaded and unloaded, and a processing station 3 equipped with various processing apparatuses for performing predetermined processes on the wafers W. The wafer processing system 1 has a configuration in which the cassette station 2, the processing station 3, and an interface station 4 for transferring wafers W with an exposure apparatus (not illustrated) adjacent to the processing station 3 on the opposite side are integrally connected. Note that, as illustrated in FIG. 1, two processing stations 3 are installed between the cassette station 2 and the interface station 4, but one processing station 3 or three or more processing stations 3 may be installed.

The cassette station 2 is provided with a plurality of cassette stages 21 and wafer transfer apparatuses 22 and 23. The cassette station 2 transfers wafers W between the cassettes C placed on the stages 21 and the processing station 3 using the wafer transfer apparatus 22 or 23. Accordingly, the wafer transfer apparatuses 22 and 23 are equipped with drive mechanisms for the X direction, Y direction, vertical direction, and around the vertical axis (θ direction), and may be equipped with drive mechanisms for all directions. At least one of the wafer transfer apparatuses 22 and 23 is configured to transfer wafers W to and from the cassette C, and is also configured to transfer wafers W to and from the processing station 3. Transferring wafers W to and from the processing station 3 includes, for example, transferring wafers W to and from a third block G3 provided with a handover apparatus accessible by a wafer transfer apparatus 33 in the processing station 3. The third block G3 may be equipped with a plurality of handover apparatuses aligned in the vertical direction.

The cassette station 2 may also be equipped with an inspection apparatus (not illustrated) for inspecting wafers W at a position accessible by either of the wafer transfer apparatuses 22 and 23.

The processing station 3 is provided with multiple blocks, for example, three blocks: a first block G1, a second block G2, and a fourth block G4. As illustrated in FIG. 2, multiple layers 31, each including the first block G1 and the second block G2, are stacked vertically. For example, the first block G1 is provided on the front part (a part in negative X direction in FIG. 1) of the processing station 3, and the second block G2 is provided on the rear part (a part in positive X direction in FIG. 1) of the processing station 3. The fourth block G4 is provided at a part near the interface station 4 (a part in positive Y direction in FIG. 1) or a connection part with another adjacent processing station 3 of the processing station 3. The fourth block G4 may be equipped with multiple handover apparatuses aligned in the vertical direction. The above-mentioned third block G3 may also be provided in the processing station 3.

The first block G1 is equipped with a plurality of processing apparatuses, such as a patterning film formation apparatus and a development apparatus, both not illustrated. The patterning film formation apparatus may include, for example, a resist film formation apparatus and, additionally, an anti-reflection film formation apparatus. For example, a plurality of processing apparatuses may be arranged horizontally. The number, arrangement, and types of these processing apparatuses can be selected freely.

In the patterning film formation apparatus and the development apparatus, a predetermined processing liquid is supplied or a predetermined gas is supplied to the wafer W, for example. In that way, a resist film used as a mask for forming a pattern in a lower-layer film is formed and an anti-reflection film for efficiently performing light irradiation processing such as exposure process is formed in the patterning film formation apparatus. In the development apparatus, part of the exposed resist film is removed to form a mask with a patterned shape as the mask.

For example, the second block G2 is equipped with heat treatment apparatuses (not illustrated) configured to perform heat processing such as heating and cooling the wafer W, arranged vertically and horizontally. The second block G2 is also equipped with a hydrophobization treatment apparatus for performing hydrophobization treatment to enhance the adhesion between a resist liquid and the wafer W, and a peripheral exposure apparatus for exposing the outer periphery of the wafer W, arranged vertically (Z direction in FIG. 2) and horizontally. The number and arrangement of these heat treatment apparatuses, hydrophobization treatment apparatuses, and peripheral exposure apparatuses can be selected freely.

As illustrated in FIG. 1, a wafer transfer area 32 is formed in the region between the first block G1 and the second block G2 in a plan view. For example, a wafer transfer apparatus 33 is arranged in the wafer transfer area 32.

The wafer transfer apparatus 33 has a transfer arm that can move in the X direction, Y direction, θ direction, and vertical direction, for example. The wafer transfer apparatus 33 is movable within the wafer transfer area 32 and can transfer wafers W to a predetermined apparatus in the surrounding first block G1, the second block G2, the third block G3, and the fourth block G4. When there are a plurality of processing stations 3 as illustrated in FIG. 1, the wafer transfer apparatus 33 in the processing station 3 located at a part near the interface station 4 can transfer wafers W to a predetermined apparatus in the first block G1, the second block G2, and the fourth block G4, as well as in a fifth block G5 described later.

A plurality of wafer transfer apparatuses 33 are arranged in the vertical direction, for example. One wafer transfer apparatus 33 can transfer wafers W to predetermined apparatuses located at the heights of upper layers 31 in the plurality of layers 31 stacked in the vertical direction (see FIG. 2). Another wafer transfer apparatus 33 can transfer wafers W to predetermined apparatuses located at the heights of layers 31 lower than those upper layers 31 in the plurality of layers 31. A plurality of wafer transfer areas 32 are provided to enable such transfer of wafers W. The number of wafer transfer apparatuses 33 and the number of layers 31 corresponding to one wafer transfer apparatus 33 can be selected freely, such as providing one wafer transfer apparatus 33 for each layer 31.

### A Shuttle Transfer Apparatus (not Illustrated) May Be Provided in

the wafer transfer area 32, or the first block G1 or the second block G2. The shuttle transfer apparatus transfers wafers W linearly between a space adjacent to one end of the processing station 3 and another space adjacent to the other end.

The interface station 4 is provided with a fifth block G5 having a plurality of handover apparatuses and wafer transfer apparatuses 41 and 42. The interface station 4 transfers, using the wafer transfer apparatuses 41 and 42, wafers W between the fifth block G5, to and from which the wafer transfer apparatus 33 delivers and receives wafer W, and the exposure apparatus. Accordingly, each of the wafer transfer apparatuses 41 and 42 is provided with drive mechanisms for the X direction, Y direction, vertical direction, and around the vertical axis (θ direction), and may be provided with drive mechanisms for all directions. At least one of the wafer transfer apparatuses 41 and 42 can support a wafer W and transfer the wafers W between the handover apparatus in the fifth block G5 and the exposure apparatus.

A cleaning apparatus for cleaning the surface of the wafer W or the above-described peripheral exposure apparatus may be provided at a position in the interface station 4 accessible for either of the wafer transfer apparatuses 41 and 42.

The inspection apparatus may be provided in the cassette station 2 as described above, but the inspection apparatus may also be provided in the processing station 3 and the interface station 4 at positions accessible by the transfer arms (33, 41, 42 in FIG. 1 or FIG. 2) provided inside each of the processing station 3 and the interface station 4.

The wafer processing system 1 is provided with a control apparatus 100. The control apparatus 100 is, for example, a computer and has a program storage unit (not illustrated). The program storage unit stores a program for controlling the processing of wafers W in the wafer processing system 1. The program storage unit also stores a program for controlling the operation of the drive systems of the various processing apparatuses and transfer apparatuses described above to realize wafer processing in the wafer processing system 1. The program may be recorded on a computer-readable storage medium H and installed in the control apparatus 100 from the storage medium H.

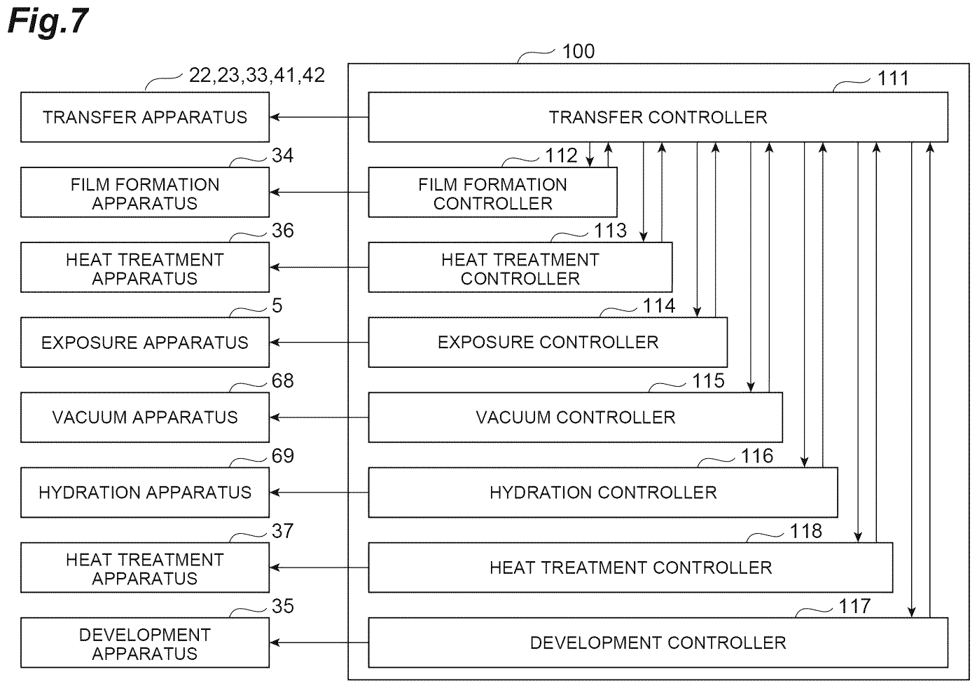

As an example, the processing station 3 includes a film formation apparatus 34 and a development apparatus 35 (see FIG. 7). The film formation apparatus 34 is an example of the patterning film formation apparatus described above and forms a photosensitive film on the surface of a substrate (for example, the wafer W). The photosensitive film may be a metal-containing resist film. The metal-containing resist film may be a negative or positive resist film containing a resist material that includes a metal compound. Containing the metal compound means that it is included as at least part of the main constituent, not as an impurity. In the case of a negative metal-containing resist film, the region where metal atom aggregates are formed by exposure can form a resist pattern without being removed by the development process. For example, the metal compound constituting the negative resist film may have metal atoms and ligands and hydroxyl groups bound to the metal atoms. Mainly due to exposure, the bond between the metal atom and the ligand is cleaved, causing the ligand to detach. Through formation of bonds resulting from reactions between metal atoms from which ligands have detached and hydroxyl groups bonded to other metal atoms and condensation reactions between hydroxyl groups, aggregates in which multiple metal atoms are bonded via oxygen atoms may be formed. In the case of a positive metal-containing resist film, the metal compound becomes hydrophilic by exposure. The region containing the hydrophilized metal compound can be removed by development process with an alkaline fluid.

The metal atoms of the metal compound constituting the resist material may be tin, tungsten, hafnium, zirconium, indium, tellurium, antimony, nickel, cobalt, titanium, tantalum, molybdenum, bismuth, iodine, germanium, or combinations thereof. The ligand may be an organic group (for example, an alkyl group). The organic group as a ligand may be substituted with a halogen atom (for example, fluorine, bromine, or iodine). Examples of alkyl groups include ethyl, isopropyl, n-propyl, t-butyl, isobutyl, n-butyl, sec-butyl, n-pentyl, isopentyl, t-pentyl, and sec-pentyl groups.

The resist film may be either negative or positive. A negative resist film becomes non-removable by the development process when exposed. After the development process, the exposed portion remains as a resist pattern on the surface of the wafer W, and the unexposed portion is removed from the surface of the wafer W. A positive resist film becomes removable by the development process when exposed. After the development process, the exposed portion is removed from the surface of the wafer W, and the unexposed portion remains as a resist pattern on the surface of the wafer W.

The film formation apparatus 34 may be of the wet type or the dry type. The wet-type film formation apparatus 34 forms a photosensitive film on the surface of the wafer W by applying a film formation liquid to the surface of the wafer W and drying the film formation liquid. The dry-type film formation apparatus 34 forms a photosensitive film on the surface of the wafer W by processing with a film formation gas such as chemical vapor deposition (CVD) without using a film formation liquid.

The development apparatus 35 performs the development process on the photosensitive film. The development process is, as described above, a process of removing the removable portion of the photosensitive film after exposure. The development apparatus 35 may be of the wet type or the dry type. The wet-type development apparatus 35 performs the development process by a wet method in which a developer solution is supplied to the photosensitive film. The removable portion of the photosensitive film after exposure dissolves in the developer solution and is removed. The dry-type development apparatus 35 performs the development process by a dry method in which a developing gas is supplied to the photosensitive film. The removable portion of the photosensitive film after exposure is removed by a chemical reaction with the developing gas. The dry-type development apparatus 35 may be configured to perform the development process in a vacuum or near-vacuum environment.

The processing station 3 may further include a heat treatment apparatus 36 and a heat treatment apparatus 37 (see FIG. 7). The heat treatment apparatus 36 performs a heating process (for example, post apply bake (PAB)) to cure the photosensitive film formed by the film formation apparatus 34. The heat treatment apparatus 37 performs a heating process (for example, post exposure bake (PEB)) on the photosensitive film after exposure process.

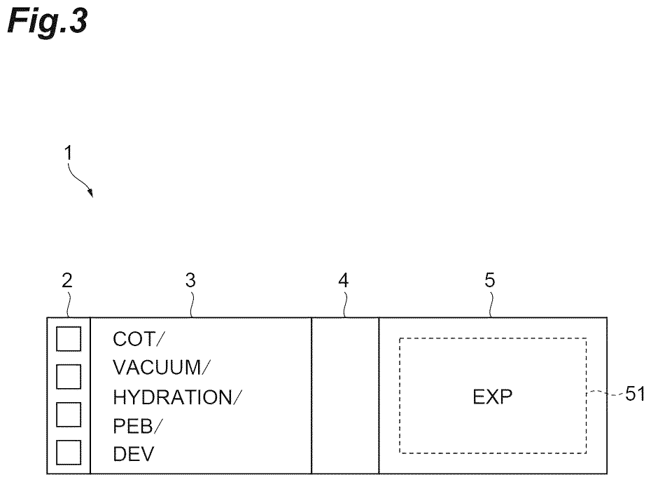

As illustrated in FIG. 3, the wafer processing system 1 may further include an exposure apparatus 5 connected to the interface station 4. The exposure apparatus 5 has a chamber 51 for accommodating the wafer W and performs an exposure process on the wafer W accommodated in the chamber 51. Examples of the exposure process include exposure with extreme ultra violet (EUV) light, exposure with argon fluoride (ArF) light, and exposure with krypton fluoride (KrF) light.

In the substrate processing by the wafer processing system 1, variations in the pattern (for example, variations in the line width of the pattern) may occur between wafers W. Variations in the pattern may also occur within a single substrate. Factors causing pattern variations include differences in the time for transferring the wafer W from the exposure apparatus 5 to the development apparatus 35 or differences in the time for transferring the wafer W from the exposure apparatus 5 to the heat treatment apparatus 37. The inventors have found that detachable substances remain in the photosensitive film and affect the pattern after the development process. Hereinafter, these substances remaining in the photosensitive film are referred to as “residual substances.” For example, differences in the period from the exposure apparatus to the heat treatment module may cause differences in the amount of residual substances, leading to pattern variations. Alternatively, differences in the progress of reactions delayed by residual substances due to differences in the above-described period may cause pattern variations.

In contrast, the wafer processing system 1 is configured to execute: performing a film formation process of a photosensitive film on the surface of the wafer W; accommodating the wafer W after the film formation process in a first chamber (for example, chamber 51) and performing an exposure process on the photosensitive film in the first chamber; accommodating the wafer W after the film formation process in a second chamber different from the first chamber and performing a pressure reduction process to depressurize the second chamber to a subatmospheric pressure; after the pressure reduction process and before the development process, performing a hydration process by subjecting the photosensitive film to a moisture-containing gas; and performing a development process on the photosensitive film of the wafer W after the exposure process and the hydration process.

According to the wafer processing system 1 configured as described above, the wafer W after the film formation process is accommodated in a second chamber different from the first chamber for exposure, and a pressure reduction process is performed to depressurize the second chamber, followed by a hydration process. Then, a development process is performed on the photosensitive film of the wafer W after the exposure process and the hydration process. The pressure reduction process forcibly reduces the residual substances. The hydration process stabilizes the state of the photosensitive film with reduced residual substances. Therefore, the influence of residual substances between wafers W after the pressure reduction process is reduced, suppressing pattern variations between wafers W. Additionally, within the photosensitive film of a single wafer W, the influence of residual substances is reduced, suppressing pattern variations within the single wafer W. The necessity to match the time from the pressure reduction process to the next process between wafers W is reduced, allowing for prioritizing the throughput time of individual wafers W and improving the efficiency of substrate processing.

The wafer processing system 1 may be configured to perform the pressure reduction process after the exposure process. Ligands detached by the exposure process can become residual substances. By performing the pressure reduction process after the exposure process, the variation in the amount of residual substances containing detached ligands can be suppressed, further suppressing pattern variations.

For example, the wafer processing system 1 may further include a pressure reduction and hydration system for performing the pressure reduction process and the hydration process. The configuration of the pressure reduction and hydration system and the control apparatus will be illustrated below.

### Vacuum and Hydration System

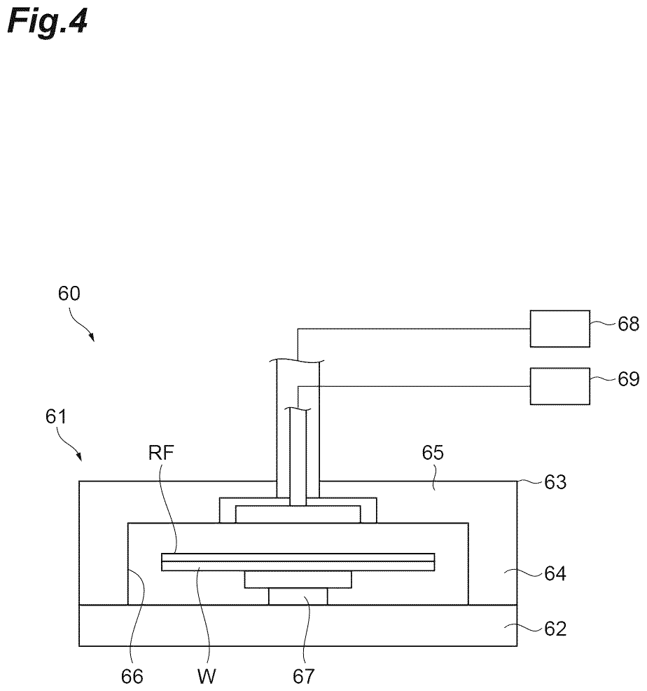

FIG. 4 is a schematic diagram illustrating an example configuration of the pressure reduction and hydration system. As illustrated in FIG. 4, the pressure reduction and hydration system 60 includes a chamber 61, a holder 67, a pressure reduction apparatus 68, and a hydration apparatus 69. The chamber 61 is isolated from an exposure chamber (chamber 51) where the wafer W is accommodated for the exposure process on the photosensitive film RF. The isolation of the chamber 61 from the chamber 51 means that the internal pressure of the chamber 61 and the internal pressure of the chamber 51 can be independently adjusted.

For example, the chamber 61 includes a base 62 and a cover 63. The base 62 has a horizontally extending upper surface. The cover 63 covers the space above and around the base 62. This forms an interior space 66 between the cover 63 and the base 62 for accommodating the wafer W. The cover 63 includes a peripheral wall 64 and a top plate 65. The peripheral wall 64 surrounds the interior space 66 around the vertical axis. The top plate 65 extends horizontally to cover the upper end surface of the peripheral wall 64. The cover 63 can move up and down relative to the base 62, and configured to open the interior space 66 to the outside by moving upward from the base 62. This allows the wafer W to be loaded into and unloaded out of the interior space 66.

The holder 67 supports the wafer W loaded into the interior space 66 from below, holding the wafer W by vacuum suction or other means. The pressure reduction apparatus 68 depressurizes the interior space 66 (inside the chamber 61) while the holder 67 holds the wafer W in the interior space 66. Depressurizing the interior space 66 means lowering the pressure in the interior space 66 below the pressure of the external space of the chamber 61. For example, the pressure reduction apparatus 68 depressurizes the interior space 66 by extracting gas from the interior space 66 using an electric pump or the like.

The hydration apparatus 69 subjects the photosensitive film RF to a moisture-containing gas. For example, the hydration apparatus 69 supplies a moisture-containing gas to the interior space 66 (inside the chamber 61) to subject the photosensitive film RF to the moisture-containing gas. For example, the hydration apparatus 69 pumps the moisture-containing gas into the interior space 66. The moisture-containing gas may be a mixed gas of an inert gas and water vapor or may be air. If the moisture-containing gas is air, the hydration apparatus 69 may be an apparatus that introduces air from the external space into the interior space 66 by connecting the interior space 66 to the external space with a valve or the like. The conditions for the hydration process in the hydration apparatus 69 can be adjusted. For example, the photosensitive film RF may be subjected to a gas or mist with a moisture concentration (humidity) equal to or higher than that of the external space air. The hydration apparatus 69 may supply, into the interior space 66, a gas with a higher concentration of oxygen, nitric oxide, or nitrogen dioxide than the external space air instead of the moisture-containing gas. The effect of the gas promoting the insolubilization reaction of the photosensitive film RF to the developing fluid can be utilized to achieve the same effect as the hydration process described later. Thus, the gas to which the photosensitive film is subjected after the pressure reduction process by the pressure reduction apparatus 68 may be any gas that contains, at least, components that improve the characteristics (for example, insolubility to the developer solution) of the exposed area by entering the photosensitive film RF instead of the residual substances from the exposure process.

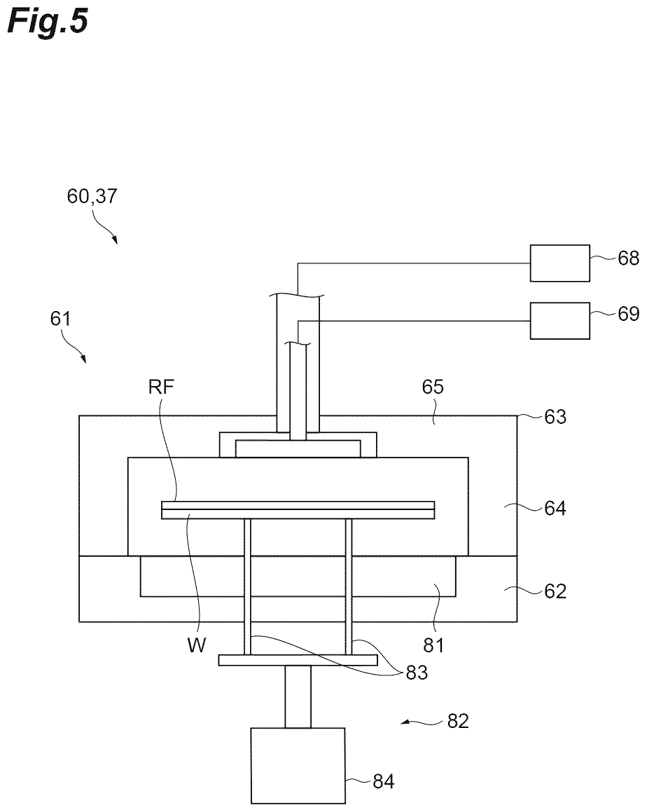

In the wafer processing system 1, the chamber 61 may be provided in any of the first block G1, the second block G2, the third block G3, the fourth block G4, or the fifth block G5 (see FIG. 1). The pressure reduction and hydration system 60 may share the chamber 61 with other apparatuses. FIG. 5 is a schematic diagram illustrating a pressure reduction and hydration system 60 that shares the chamber 61 with the heat treatment apparatus 37.

As illustrated in FIG. 5, the pressure reduction and hydration system 60 and the heat treatment apparatus 37 share the chamber 61 described above. The heat treatment apparatus 37 further includes a hot plate 81 and a lifting device 82. The hot plate 81 extends horizontally and is supported by the base 62. The hot plate 81 incorporates a heater such as an electric heating wire and generates heat to heat the photosensitive film RF. The lifting device 82 supports and lifts the wafer W on the hot plate 81. For example, the lifting device 82 includes multiple lifting pins 83 that penetrate the base 62 and the hot plate 81 from below to support the wafer W, and a lifting actuator 84 that lifts the multiple lifting pins 83. Since the wafer W is supported by the multiple lifting pins 83, the pressure reduction and hydration system 60 does not have to include the holder 67 described above.

In order to perform a pressure reduction process and a hydration process before the heating by the heat treatment apparatus 37, the pressure reduction apparatus 68 depressurizes the chamber 61 while the lifting device 82 lifts the multiple lifting pins 83, separating the wafer W from the hot plate 81. The hydration apparatus 69 supplies the moisture-containing gas to the interior space 66 while the wafer W is separated from the hot plate 81.

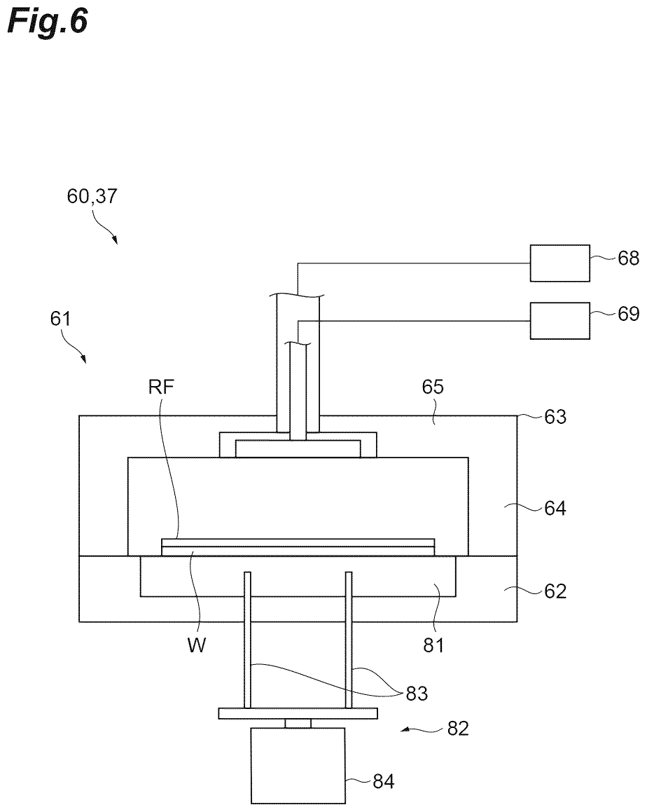

As illustrated in FIG. 6, the heat treatment apparatus 37 causes the hot plate 81 to support the wafer W by lowering the multiple lifting pins 83 with the lifting device 82. This allows the hot plate 81 to heat the wafer W. When the pressure reduction and hydration system 60 and the heat treatment apparatus 37 share the chamber 61, the wafer W after the pressure reduction process and the hydration process can be considered to be transferred to the heat treatment apparatus 37 by the lifting device 82. Compared to the case where the heat treatment apparatus 37 and the pressure reduction and hydration system 60 each have separate chambers, the transfer distance of the wafer W after the pressure reduction process and the hydration process to the heat treatment apparatus 37 can be shortened.

### Control Apparatus

As illustrated in FIG. 7, the control apparatus 100 includes such as a transfer controller 111, a film formation controller 112, a heat treatment controller 113, an exposure controller 114, a vacuum controller 115, a hydration controller 116, and a development controller 117 as functional constituents (hereinafter referred to as “functional blocks”). The transfer controller 111 controls the wafer transfer apparatuses 22, 23, 33, 41, and 42 to transfer the wafer W. For example, the transfer controller 111 controls the wafer transfer apparatuses 22, 23, and 33 to transfer the wafer W from the cassette C to the film formation apparatus 34 and controls the wafer transfer apparatus 33 to transfer the wafer W after the film formation process from the film formation apparatus 34 to the heat treatment apparatus 36. The transfer controller 111 also controls the wafer transfer apparatuses 33, 41, and 42 to transfer the wafer W after the film formation process from the heat treatment apparatus 36 to the exposure apparatus 5.

The transfer controller 111 controls the wafer transfer apparatuses 33, 41, and 42 to load the wafer W after the film formation process and the exposure process from the exposure apparatus 5 into the chamber 61. The transfer controller 111 controls the wafer transfer apparatuses 22, 23, and 33 to unload the wafer W after the hydration process from the chamber 61 and transfer the wafer W to the development apparatus 35, and to transfer the wafer W after the development process from the development apparatus 35 to the cassette C.

The film formation controller 112 controls the film formation apparatus 34 to perform the film formation process of the photosensitive film RF on the wafer W transferred by the transfer controller 111. The heat treatment controller 113 controls the heat treatment apparatus 36 to perform the heating process of the photosensitive film RF on the wafer W after the film formation process transferred by the transfer controller 111. The exposure controller 114 controls the exposure apparatus 5 to perform the exposure process of the photosensitive film RF on the wafer W after the film formation process transferred by the transfer controller 111.

The vacuum controller 115 controls the pressure reduction apparatus 68 to depressurize the interior space 66 after the wafer W subjected to the exposure process is loaded into the chamber 61 and before the wafer W is unloaded from the chamber 61. The hydration controller 116 controls the hydration apparatus 69 to subject the photosensitive film RF to the moisture-containing gas after the interior space 66 is depressurized and before the wafer W is transferred to the development apparatus 35. For example, the hydration controller 116 controls the hydration apparatus 69 to pump the moisture-containing gas into the interior space 66 while the interior space 66 accommodates the wafer W and is depressurized. The development controller 117 controls the development apparatus 35 to perform the development process of the photosensitive film RF on the wafer W after the hydration process transferred by the transfer controller 111.

The wafer processing system 1 may perform the exposure process while maintaining the interior of the chamber 51 at a subatmospheric pressure. For example, the exposure controller 114 may control the exposure apparatus 5 to perform the exposure process while maintaining the interior of the chamber 51 at a subatmospheric pressure.

By depressurizing the interior of the chamber 51, the influence of the exposure process on the photosensitive film RF can be stabilized. On the other hand, differences in the elapsed time from the exposure timing to the unloading timing from the chamber 51 may cause variations in the amount of residual substances. The variations in the amount of residual substances caused in this way can be reduced by the pressure reduction process after the exposure process. Therefore, both stabilization of the influence of the exposure process and suppression of variations in the amount of residual substances can be achieved.

The exposure apparatus 5 may be configured to perform the exposure process on the photosensitive film RF of the wafer W in the chamber 51 using a stitching method. The stitching method is a method in which multiple exposures are performed using multiple masks (or reticles) for each of the multiple exposure fields arranged along the surface of the wafer W. For example, each of the multiple exposure fields is divided into a first field and a second field, and the first field is exposed using a first mask, and the second field is exposed using a second mask different from the first mask. The exposure range of the first mask and the exposure range of the second mask may partially overlap in each of the multiple exposure fields.

In the stitching method, after performing exposure using the first mask continuously for all exposure fields, exposure using the second mask may be performed. The first field and the second field are different in the time for being placed in the depressurized environment of the chamber 51. This may cause differences in the amount of residual substances between the first field and the second field, potentially resulting in differences in line width between the first field and the second field. Even in such cases, the pressure reduction process after the exposure process can reduce the differences in the amount of residual substances between the first field and the second field. Therefore, the pressure reduction process and the hydration process after the exposure process are also beneficial in suppressing differences in line width between fields in the stitching method.

The wafer processing system 1 may perform the exposure process while maintaining the interior of the chamber 51 at a first subatmospheric pressure, and in the pressure reduction process, the interior of the chamber 61 may be depressurized to a second subatmospheric pressure higher than the first pressure.

For example, the exposure controller 114 may control the exposure apparatus 5 to perform the exposure process while maintaining the interior of the chamber 51 at the first subatmospheric pressure. The vacuum controller 115 may control the pressure reduction apparatus 68 to depressurize the interior of the chamber 61 to the second subatmospheric pressure higher than the first subatmospheric pressure and not to depressurize the interior of the chamber 61 to the first subatmospheric pressure.

The first subatmospheric pressure is, for example, 1/100000 Pa or less. The second subatmospheric pressure is, for example, 1 to 80000 Pa. The second subatmospheric pressure may be 5 to 60000 Pa. For example, the second subatmospheric pressure is 10 to 30 Pa. It may take a long time to reach the first subatmospheric pressure. For example, it may take several tens of seconds or more to depressurize from near atmospheric pressure to 1/100000 Pa or less (ultra-high vacuum). In contrast, by setting the pressure in the pressure reduction process to the second subatmospheric pressure higher than the first subatmospheric pressure, the decrease in processing efficiency due to the pressure reduction process can be suppressed.

The vacuum controller 115 may maintain the pressure in the chamber 61 at the post-depressurization pressure for at least a predetermined period in the pressure reduction process. The predetermined period may be, for example, 10 to 20 seconds, 10 to 60 seconds, or 30 seconds. The variations in the influence of residual substances between wafers W and within a single wafer W can be further suppressed by the pressure reduction process.

The wafer processing system 1 may be configured to perform a heating process on the photosensitive film RF after the hydration process and before the development process. By supplementing the exposure process with the heating process, the energy consumption of the exposure process can be reduced. On the other hand, residual substances may also affect the effect of the heating process. By suppressing the variations in the amount of residual substances through the pressure reduction process and further improving the stability of the photosensitive film state through the hydration process, the variations in the effect of the heating process can also be suppressed. In the heating process, the wafer W may be heated to 100 to 300° C., may be heated to 150 to 250° C., or may be heated to 180 to 220° C.

For example, the transfer controller 111 may control the wafer transfer apparatus 33 to transfer the wafer W after the hydration process from the chamber 61 to the heat treatment apparatus 37 and to transfer the wafer W after the heat treatment from the heat treatment apparatus 37 to the development apparatus 35. The control apparatus 100 may further include a heat treatment controller 118. The heat treatment controller 118 controls the heat treatment apparatus 37 to perform the heating process on the photosensitive film RF of the wafer W after the hydration process transferred by the transfer controller 111. The hydration controller 116 controls the hydration apparatus 69 to subject the photosensitive film RF to the moisture-containing gas after the interior space 66 is depressurized and before the wafer W is transferred to the heat treatment apparatus 37.

The wafer processing system 1 may be configured to perform a first heating process on the photosensitive film after the exposure process and before the pressure reduction process, and a second heating process on the photosensitive film after the hydration process and before the development process. By performing the first heating process before the pressure reduction process, the variations in the amount of residual substances can be further suppressed. By suppressing the variations in the amount of residual substances, the variations in the effect of the second heating process can also be suppressed.

For example, the transfer controller 111 may control the wafer transfer apparatuses 33, 41, and 42 to transfer the wafer W after the film formation process and the exposure process from the exposure apparatus 5 to the heat treatment apparatus 37. The transfer controller 111 may control the wafer transfer apparatus 33 to load the wafer W after the first heating process from the heat treatment apparatus 37 into the chamber 61. Furthermore, the transfer controller 111 may control the wafer transfer apparatus 33 to transfer the wafer W after the hydration process from the chamber 61 to the heat treatment apparatus 37 and to transfer the wafer W after the second heating process from the heat treatment apparatus 37 to the development apparatus 35.

The heat treatment controller 118 controls the heat treatment apparatus 37 to perform the first heating process on the photosensitive film RF of the wafer W after the film formation process and the exposure process transferred by the transfer controller 111. The heat treatment controller 118 controls the heat treatment apparatus 37 to perform the second heating process on the photosensitive film RF of the wafer W after the hydration process transferred by the transfer controller 111.

In the first heating process, the wafer W may be heated to a first temperature, and in the second heating process, the wafer W may be heated to a second temperature higher than the first temperature. By sufficiently reducing the amount of residual substances and then heating at a high temperature, thermal energy can be utilized. For example, the first temperature may be 10 to 50° C. lower than the second temperature, 10 to 40° C. lower, or 10 to 30° C. lower.

The wafer processing system 1 may not be configured to perform the heating process on the photosensitive film RF after the hydration process and before the development process. For example, the wafer processing system 1 may be configured to perform the first heating process and not to perform the second heating process.

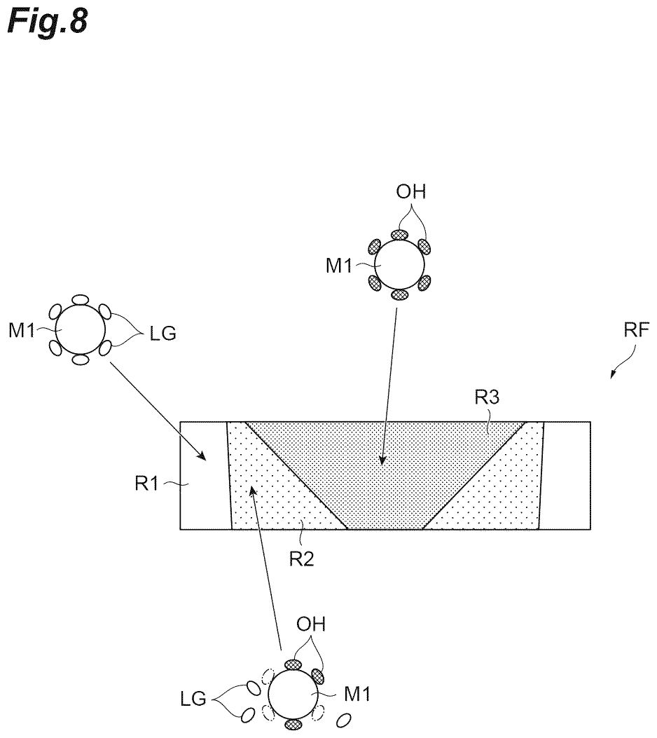

Hereinafter, the effects of the pressure reduction process and the hydration process will be illustrated with reference to FIGS. 8, 9A, 9B, 9C, 9D, 9E, 10A, 10B, 10C, 10D, 10E, 10F, and 10G. FIG. 8 is a schematic diagram illustrating the state of the photosensitive film RF immediately after the exposure process. FIG. 8 illustrates a cross-section of the exposed area and its surrounding area in the photosensitive film RF.

As illustrated in FIG. 8, the photosensitive film RF immediately after the exposure process is considered to include an unexposed area R1, a partially substituted area R2, and a substituted area R3. The unexposed area R1 is the region where the exposure light was not irradiated during the exposure process. In the unexposed area R1, ligands LG are bonded to a molecule M1 (for example, a molecule containing a metal atom) constituting the photosensitive film.

The partially substituted area R2 and the substituted area R3 are regions where the exposure light was irradiated during the exposure process. In the substituted area R3, the ligands LG attached to the molecule M1 have been replaced by hydroxyl groups OH. For example, hydroxyl groups OH are bonded to the sites where the ligands LG were detached by the exposure process. In the partially substituted area R2, a molecule M1 with unbonded sites where the ligands LG were detached by the exposure process and hydroxyl groups OH have not yet bonded are present.

The bonding of hydroxyl groups OH to the unbonded sites is considered to gradually progress after the exposure process, hindered by residual substances such as the detached ligands LG. Therefore, the size of the partially substituted area R2 and the substituted area R3 may vary between wafers W due to differences in the elapsed time after the exposure process. The amount of residual substances may also vary depending on the part in the photosensitive film RF. For example, the amount of residual substances may increase with the depth from the surface of the photosensitive film RF. FIG. 8 illustrates a state where the partially substituted area R2 increases and the width of the substituted area R3 decreases with the depth from the surface of the photosensitive film RF because the amount of residual substances increases as the depth from the surface of the photosensitive film RF increases.

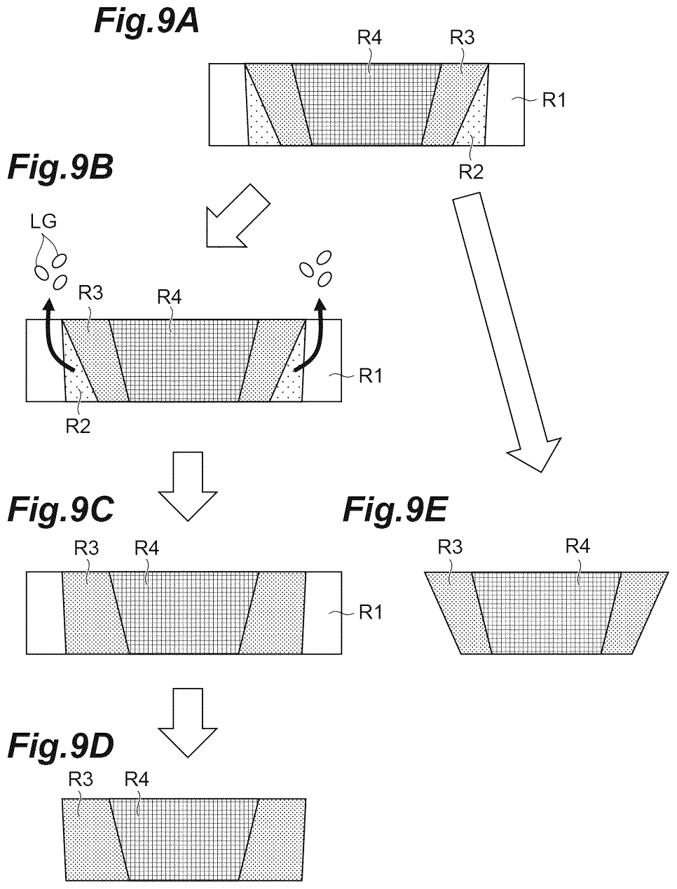

FIGS. 9A, 9B, 9C, 9D, and 9E are schematic diagrams illustrating the state changes of the photosensitive film RF when the first heating process is performed on a negative photosensitive film RF, and the second heating process is not performed, and the wet-type development process is performed. When the first heating process is performed on the wafer W after the exposure process, as illustrated in FIG. 9A, a condensed area R4 is newly formed in the photosensitive film RF. The condensed area R4 is a region where the molecules M1 have polymerized through dehydration condensation of the molecules M1 in the substituted area R3. In the partially substituted area R2, dehydration condensation is less likely to occur, so the partially substituted area R2 remains even after the first heating process. A part of the substituted area R3 also remains.

As illustrated in FIG. 9B, the pressure reduction apparatus 68 may depressurize the chamber 61 in the pressure reduction process to extract residual substances, including the ligands LG detached through the exposure process, from the partially substituted area R2. This reduces the residual substances in the photosensitive film RF. The hydration apparatus 69 may subject the photosensitive film RF to the moisture-containing gas in the hydration process to bond hydroxyl groups OH to the unbonded sites of the molecule M1 (replace the detached ligands LG detached in the exposure process with hydroxyl groups OH). As a result, as illustrated in FIG. 9C, the remaining partially substituted area R2 is converted to the substituted area R3. Then, when the development process is performed, the unexposed area R1 dissolves in the developer solution and is removed. As a result, as illustrated in FIG. 9D, the substituted area R3 and the condensed area R4 remain to form the resist pattern.

If the pressure reduction process and the hydration process are not performed, the partially substituted area R2 dissolves in the developer solution along with the unexposed area R1. Therefore, as illustrated in FIG. 9E, a resist pattern with a smaller line width is formed compared to when the pressure reduction process and the hydration process are performed. The degree to which the line width becomes smaller compared to when the pressure reduction process and the hydration process are performed depends on the size of the partially substituted area R2. As described above, the size of the partially substituted area R2 varies depending on the elapsed time after the exposure process. Therefore, variations in line width may occur depending on the elapsed time after the exposure process.

Additionally, if the size of the partially substituted area R2 increases and the width of the substituted area R3 decreases with the depth from the surface of the photosensitive film RF, a resist pattern with a smaller line width near the surface of the wafer W, which is prone to collapse, is formed.

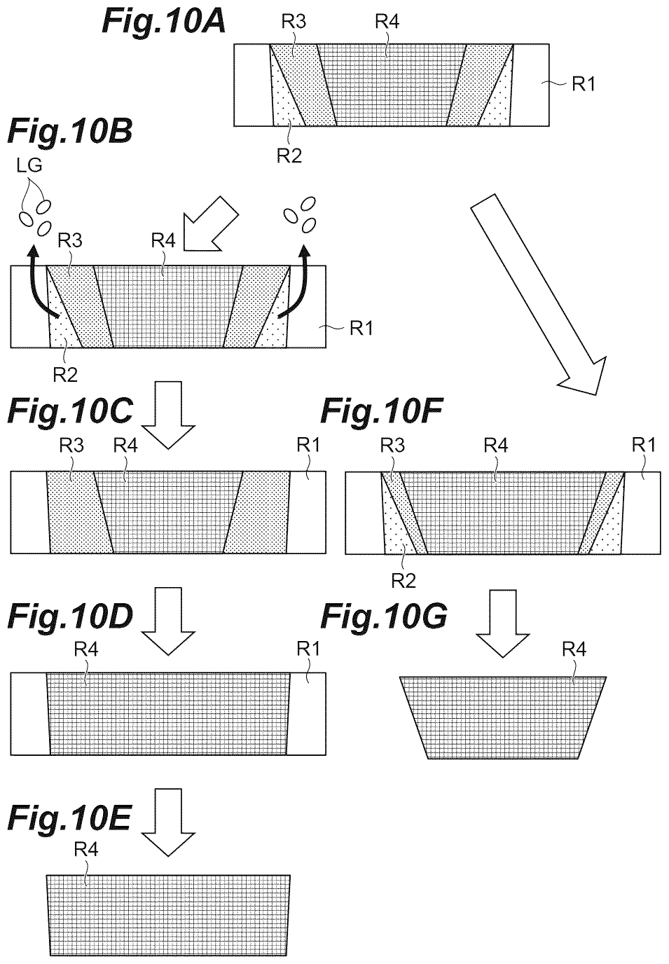

FIGS. 10A, 10B, 10C, 10D, 10E, 10F, and 10G are schematic diagrams illustrating the state changes of the photosensitive film RF when the first heating process is performed on a negative photosensitive film RF, the second heating process is performed, and the dry-type development process is performed. As described above, when the first heating process is performed on the wafer W after the exposure process, as illustrated in FIG. 10A, a condensed area R4 is newly formed in the photosensitive film RF.

As illustrated in FIG. 10B, in the pressure reduction process, the residual substances, including the ligands LG detached through the exposure process, are extracted from the partially substituted area R2. As illustrated in FIG. 10C, in the hydration process, hydroxyl groups OH bond to the unbonded sites of the molecules M1, converting the partially substituted area R2 to the substituted area R3.

Then, when the second heating process is performed, as illustrated in FIG. 10D, dehydration condensation progresses in the substituted area R3, converting the substituted area R3 to the condensed area R4. Even in the portion converted to the condensed area R4 by the hydration process, the molecules M1, where the ligand LG is replaced by hydroxyl groups OH, undergo dehydration condensation. Then, when the development process is performed, the unexposed area R1 is removed. As a result, as illustrated in FIG. 10E, the condensed area R4 remains to form the resist pattern.

If the pressure reduction process and the hydration process are not performed, the second heating process is performed with the partially substituted area R2 remaining. Therefore, as illustrated in FIG. 10F, even if the substituted area R3 is converted to the condensed area R4, the partially substituted area R2 remains. Then, when the dry development process is performed, the unexposed area R1 and the partially substituted area R2 are removed. Therefore, as illustrated in FIG. 10G, a resist pattern with a smaller line width is formed compared to when the pressure reduction process and the hydration process are performed. The degree to which the line width becomes smaller compared to when the pressure reduction process and the hydration process are performed depends on the size of the partially substituted area R2. As described above, the size of the partially substituted area R2 varies depending on the elapsed time after the exposure process. Therefore, variations in line width may occur depending on the elapsed time after the exposure process.

The residual substances may not be limited to the ligand LG. For example, the residual substances may contain components of the organic solvent of the film formation liquid that remain in the photosensitive film RF even after heating by the heat treatment apparatus 36. The components of the organic solvent can be removed even before the exposure process. The wafer processing system 1 may be configured to perform the pressure reduction process before the exposure process.

For example, the transfer controller 111 controls the wafer transfer apparatus 33 to load the wafer W after the film formation process from the heat treatment apparatus 36 into the chamber 61. The transfer controller 111 controls the wafer transfer apparatuses 33, 41, and 42 to transfer the wafer W after the pressure reduction process to the exposure apparatus 5. The transfer controller 111 controls the wafer transfer apparatuses 33, 41, and 42 to transfer the wafer W after the film formation process and the exposure process from the exposure apparatus 5 to the heat treatment apparatus 37 or the development apparatus 35. If there is a timing when the wafer W is exposed to air between the exposure process and the development process, the ligands LG are replaced by hydroxyl groups OH at that timing. Therefore, after the exposure process, loading the wafer W into the chamber 61 for the hydration process may be omitted. The hydration apparatus 69 may be omitted from the configuration of the wafer processing system 1.

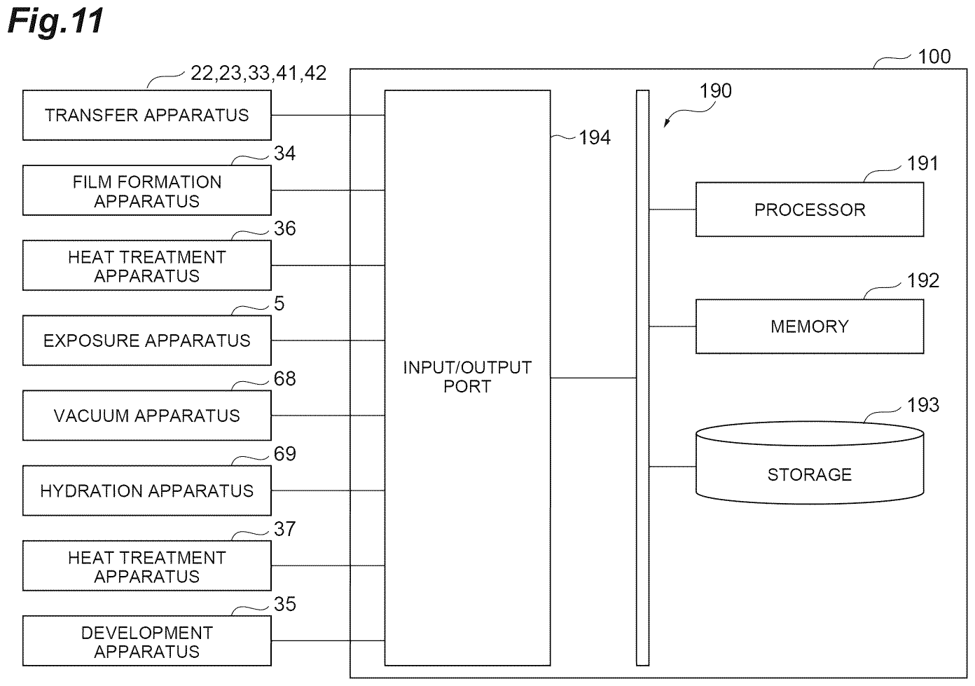

FIG. 11 is a block diagram illustrating an example hardware configuration of the control apparatus 100. As illustrated in FIG. 11, the control apparatus 100 includes circuitry 190. The circuitry 190 includes a processor 191, a memory 192, storage 193, and an input/output port 194.

The storage 193 includes, for example, one or more non-volatile storage media. The non-volatile storage media include one or more storage devices. Examples of storage devices include hard disk drives, solid-state drives, and flash memory. The non-volatile storage media may include portable storage media such as optical discs. The storage 193 stores a program for causing the wafer processing system 1 to execute: performing a film formation process of a photosensitive film on the surface of the wafer W; accommodating the wafer W after the film formation process in a first chamber (for example, chamber 51) and performing an exposure process on the photosensitive film in the first chamber; accommodating the wafer W after the film formation process in a second chamber different from the first chamber and performing a pressure reduction process to depressurize the second chamber; after the pressure reduction process and before the development process, performing a hydration process by subjecting the photosensitive film to a moisture-containing gas; and performing a development process on the photosensitive film of the wafer W after the exposure process and the hydration process. For example, the storage 193 stores a program for causing the control apparatus 100 to configure the functional blocks described above.

The memory 192 includes one or more volatile storage media. The volatile storage media include one or more memory devices. Examples of memory devices include random access memory. The memory 192 temporarily stores the program loaded from the storage 193. The processor 191 includes one or more arithmetic devices. Examples of arithmetic devices include a central processing unit (CPU) or a graphics processing unit (GPU). The processor 191 executes the program loaded into the memory 192 to cause the control apparatus 100 to configure the functional blocks described above. The processor 191 may temporarily store the calculation results in the memory 192.

The input/output port 194 inputs and outputs control signals to and from the wafer transfer apparatuses 22, 23, 33, 41, 42, the film formation apparatus 34, the development apparatus 35, the heat treatment apparatus 36, the heat treatment apparatus 37, the exposure apparatus 5, the pressure reduction apparatus 68, and the hydration apparatus 69 based on requests from the processor 191.

The configuration of the control apparatus 100 illustrated above is an example and can be modified. Not all of the functional blocks described above may be configured by executing the program in the storage 193. For example, at least some of the functional blocks may be configured by circuitry specialized for their functions, such as application specific integrated circuits (ASICs).

In the above, an example is illustrated where the film formation apparatus 34, the heat treatment apparatus 36, the exposure apparatus 5, the pressure reduction apparatus 68, the hydration apparatus 69, the heat treatment apparatus 37, and the development apparatus 35 are integrated into one apparatus. These may be divided into multiple apparatuses, and each of the multiple apparatuses may have its own cassette station 2 independently. It is sufficient that at least one of the apparatuses includes a chamber 61 isolated from the chamber 51, a pressure reduction apparatus 68, a hydration apparatus 69, a transfer apparatus (for example, wafer transfer apparatuses 22, 23, 33), a transfer controller 111, a vacuum controller 115, and a hydration controller 116.

The transfer controller 111 controls the wafer transfer apparatus 33 to load and unload the wafer W after the exposure process for the photosensitive film RF and before the development process for the photosensitive film RF into and out of the chamber 61. The vacuum controller 115 controls the pressure reduction apparatus 68 to depressurize the chamber 61 after the wafer W is loaded into the chamber 61 and before the wafer W is unloaded from the chamber 61. The hydration controller 116 controls the hydration apparatus 69 to subject the photosensitive film RF to the moisture-containing gas after the interior of the chamber 61 is depressurized.

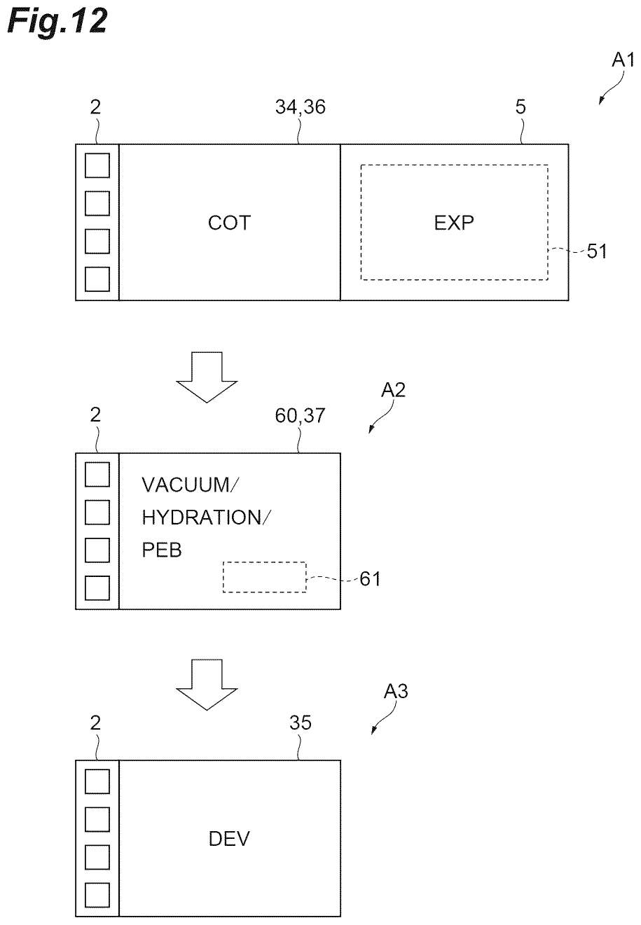

FIG. 12 is a schematic diagram illustrating a case where the film formation apparatus 34, the heat treatment apparatus 36, the exposure apparatus 5, the pressure reduction apparatus 68, the hydration apparatus 69, the heat treatment apparatus 37, and the development apparatus 35 are divided into apparatuses A1, A2, and A3. The apparatus A1 includes the cassette station 2, the film formation apparatus 34, the heat treatment apparatus 36, and the exposure apparatus 5. The apparatus A1 performs the film formation process by the film formation apparatus 34, the heating process by the heat treatment apparatus 36, and the exposure process by the exposure apparatus 5 on the wafer W taken out from the cassette C, and returns the wafer W after the exposure process to the cassette C.

The cassette C containing the wafer W after the exposure process is transferred to the cassette station 2 of the apparatus A2. The apparatus A2 includes the cassette station 2, the pressure reduction and hydration system 60, and the heat treatment apparatus 37. The apparatus A2 performs the pressure reduction process by the pressure reduction apparatus 68, the hydration process by the hydration apparatus 69, and the heating process by the heat treatment apparatus 37 on the wafer W taken out from the cassette C, and returns the wafer W after the heating process to the cassette C. In the configuration of FIG. 12, the chamber 61 of the pressure reduction and hydration system 60 is isolated from the chamber 51 of the exposure apparatus 5.

The cassette C containing the wafer W after the heating process is transferred to the cassette station 2 of the apparatus A3. The apparatus A3 includes the development apparatus 35. The apparatus A3 performs the development process by the development apparatus 35 on the wafer W taken out from the cassette C and returns the wafer W after the development process to the cassette C.

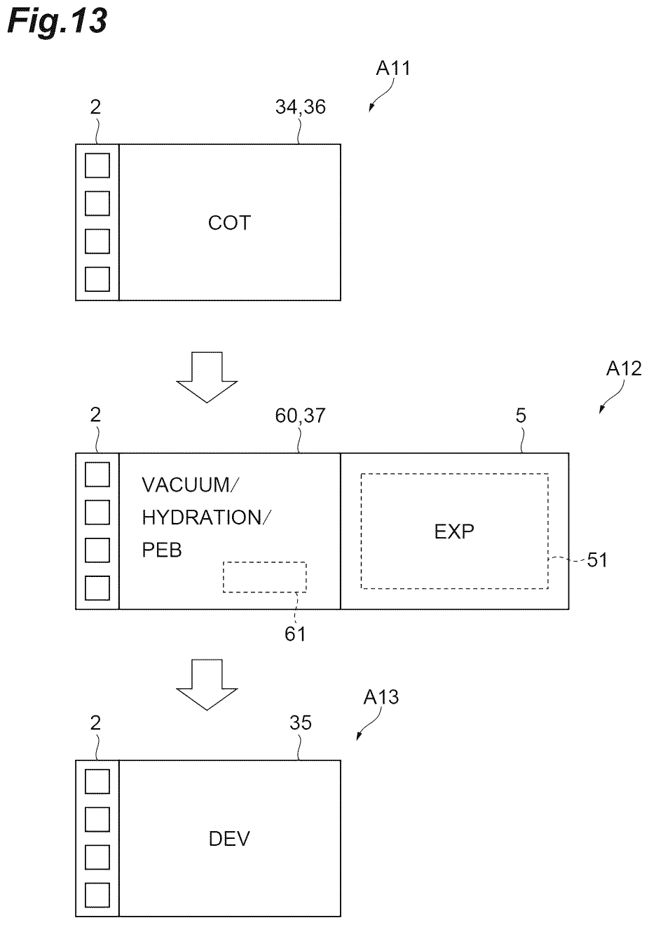

FIG. 13 is a schematic diagram illustrating a case where the film formation apparatus 34, the heat treatment apparatus 36, the exposure apparatus 5, the pressure reduction apparatus 68, the hydration apparatus 69, the heat treatment apparatus 37, and the development apparatus 35 are divided into apparatuses A11, A12, and A13. The apparatus A11 includes the cassette station 2, the film formation apparatus 34, and the heat treatment apparatus 36. The apparatus A11 performs the film formation process by the film formation apparatus 34 and the heating process by the heat treatment apparatus 36 on the wafer W taken out from the cassette C, and returns the wafer W after the heating process to the cassette C.

The cassette C containing the wafer W after the heating process by the heat treatment apparatus 36 is transferred to the cassette station 2 of the apparatus A12. The apparatus A12 includes the exposure apparatus 5, the pressure reduction apparatus 68, the hydration apparatus 69, and the heat treatment apparatus 37. The apparatus A12 performs the exposure process by the exposure apparatus 5, the pressure reduction process by the pressure reduction apparatus 68, the hydration process by the hydration apparatus 69, and the heating process by the heat treatment apparatus 37 on the wafer W taken out from the cassette C, and returns the wafer W after the heating process to the cassette C. In the apparatus A12, the chamber 61 of the pressure reduction and hydration system 60 is isolated from the chamber 51 of the exposure apparatus 5.

The cassette C containing the wafer W after the heating process the heat treatment apparatus 37 is transferred to the cassette station 2 of the apparatus A13. The apparatus A13 includes the development apparatus 35. The apparatus A13 performs the development process by the development apparatus 35 on the wafer W taken out from the cassette C and returns the wafer W after the development process to the cassette C.

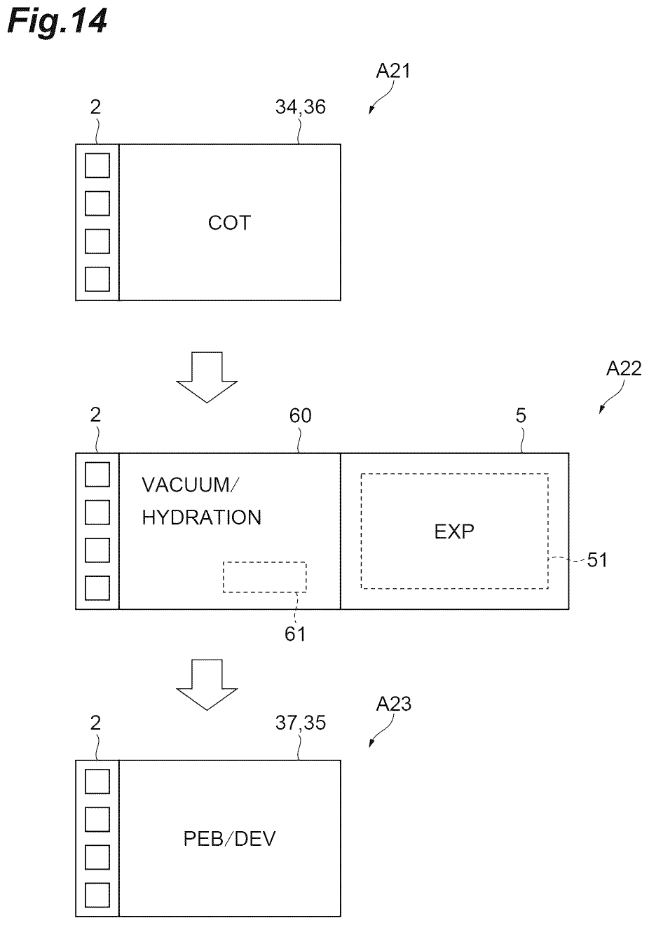

FIG. 14 is a schematic diagram illustrating a case where the film formation apparatus 34, the heat treatment apparatus 36, the exposure apparatus 5, the pressure reduction apparatus 68, the hydration apparatus 69, the heat treatment apparatus 37, and the development apparatus 35 are divided into apparatuses A21, A22, and A23. The apparatus A21 includes the cassette station 2, the film formation apparatus 34, and the heat treatment apparatus 36. The apparatus A21 performs the film formation process by the film formation apparatus 34 and the heating process by the heat treatment apparatus 36 on the wafer W taken out from the cassette C, and returns the wafer W after the heating process to the cassette C.

The cassette C containing the wafer W after the heating process with the heat treatment apparatus 36 is transferred to the cassette station 2 of the apparatus A22. The apparatus A22 includes the exposure apparatus 5, the pressure reduction apparatus 68, and the hydration apparatus 69. The apparatus A22 performs the exposure process by the exposure apparatus 5, the pressure reduction process by the pressure reduction apparatus 68, and the hydration process by the hydration apparatus 69 on the wafer W taken out from the cassette C, and returns the wafer W after the hydration process to the cassette C. In the apparatus A22, the chamber 61 of the pressure reduction and hydration system 60 is isolated from the chamber 51 of the exposure apparatus 5.

The cassette C containing the wafer W after the hydration process is transferred to the cassette station 2 of the apparatus A23. The apparatus A23 includes the heat treatment apparatus 37 and the development apparatus 35. The apparatus A23 performs the heating process by the heat treatment apparatus 37 and the development process by the development apparatus 35 on the wafer W taken out from the cassette C, and returns the wafer W after the development process to the cassette C.

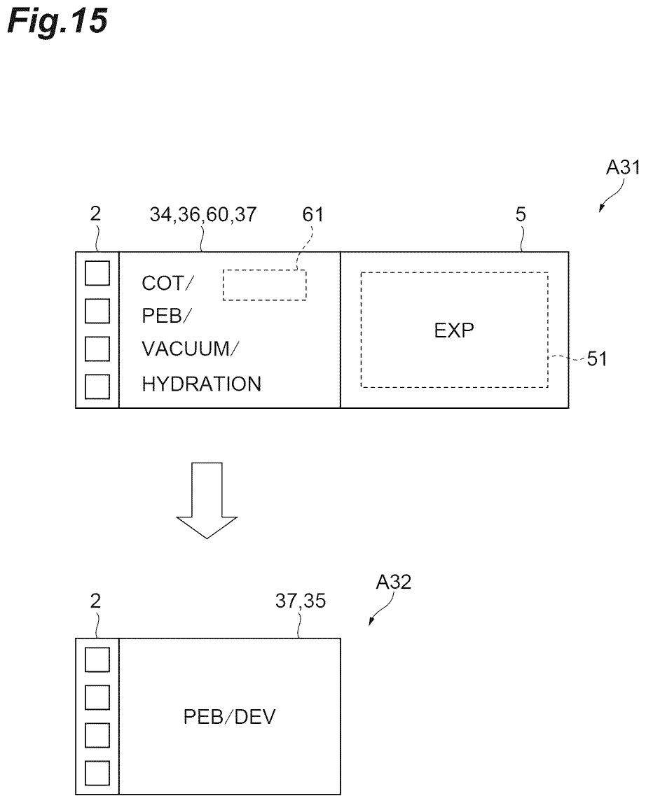

FIG. 15 is a schematic diagram illustrating a case where the film formation apparatus 34, the heat treatment apparatus 36, the exposure apparatus 5, the pressure reduction apparatus 68, the hydration apparatus 69, the heat treatment apparatus 37, and the development apparatus 35 are divided into apparatuses A31 and A32. The apparatus A31 includes the film formation apparatus 34, the heat treatment apparatus 36, the exposure apparatus 5, the pressure reduction apparatus 68, and the hydration apparatus 69. The apparatus A31 performs the film formation process by the film formation apparatus 34, the heating process by the heat treatment apparatus 36, the exposure process by the exposure apparatus 5, the pressure reduction process by the pressure reduction apparatus 68, and the hydration process by the hydration apparatus 69 on the wafer W taken out from the cassette C, and returns the wafer W after the hydration process to the cassette C. In the apparatus A31, the chamber 61 of the pressure reduction and hydration system 60 is isolated from the chamber 51 of the exposure apparatus 5.

The cassette C containing the wafer W after the hydration process is transferred to the cassette station 2 of the apparatus A32. The apparatus A32 includes the heat treatment apparatus 37 and the development apparatus 35. The apparatus A32 performs the heating process by the heat treatment apparatus 37 and the development process by the development apparatus 35 on the wafer W taken out from the cassette C, and returns the wafer W after the development process to the cassette C.

### Substrate Processing Procedure

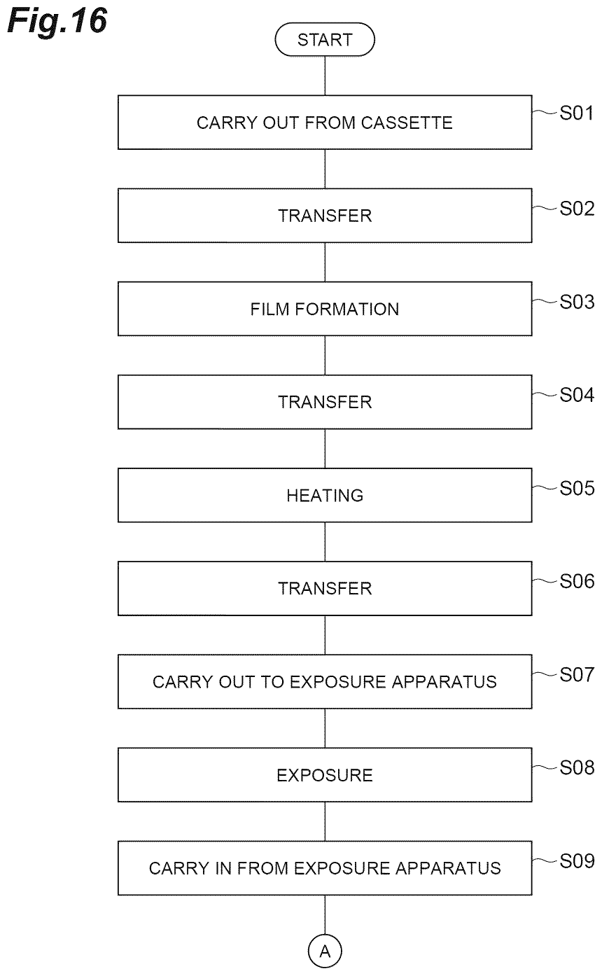

As an example of the substrate processing method, an example substrate processing procedure executed by the wafer processing system 1 will be illustrated. The following procedure includes both the first heating process and the second heating process described above. As illustrated in FIG. 16, the wafer processing system 1 executes operations S01, S02, S03, S04, and S05. In operation S01, the transfer controller 111 controls the wafer transfer apparatuses 22 and 23 to take out the wafer W from the cassette C. In operation S02, the transfer controller 111 controls the wafer transfer apparatus 33 to transfer the wafer W taken out from the cassette C to the film formation apparatus 34. In operation S03, the film formation controller 112 controls the film formation apparatus 34 to perform the film formation process on the wafer W transferred by the wafer transfer apparatus 33. In operation S04, the transfer controller 111 controls the wafer transfer apparatus 33 to transfer the wafer W after the film formation process from the film formation apparatus 34 to the heat treatment apparatus 36. In operation S05, the heat treatment controller 113 controls the heat treatment apparatus 36 to perform the heating process on the wafer W transferred by the wafer transfer apparatus 33.

Next, the wafer processing system 1 executes operations S06, S07, S08, and S09. In operation S06, the transfer controller 111 controls the wafer transfer apparatus 33 to transfer the wafer W after the heating process from the heat treatment apparatus 36. In operation S07, the transfer controller 111 controls the wafer transfer apparatuses 41 and 42 to transfer the wafer W transferred by the wafer transfer apparatus 33 to the exposure apparatus 5. In operation S08, the exposure controller 114 controls the exposure apparatus 5 to perform the exposure process on the wafer W transferred by the wafer transfer apparatuses 41 and 42. In operation S09, the transfer controller 111 controls the wafer transfer apparatuses 41 and 42 to transfer the wafer W after the exposure process from the exposure apparatus 5.

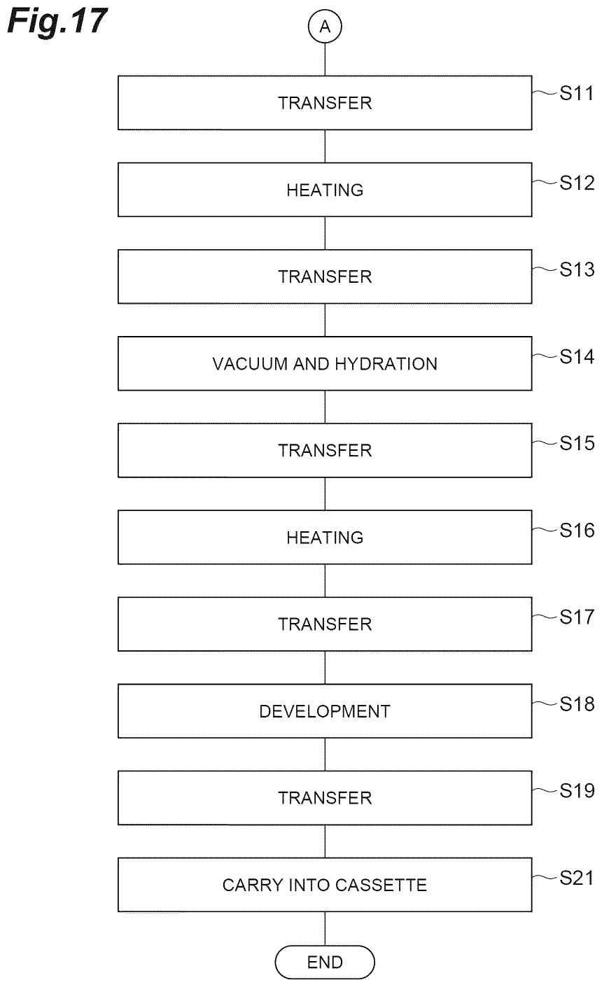

Next, as illustrated in FIG. 17, the wafer processing system 1 executes operations S11 and S12. In operation S11, the transfer controller 111 controls the wafer transfer apparatus 33 to transfer the wafer W after the exposure process transferred by the wafer transfer apparatuses 41 and 42 to the heat treatment apparatus 37. In operation S12, the heat treatment controller 118 controls the heat treatment apparatus 37 to perform the first heating process on the wafer W transferred by the wafer transfer apparatus 33.

Next, the wafer processing system 1 executes operations S13 and S14. In operation S13, the transfer controller 111 controls the wafer transfer apparatus 33 to load the wafer W after the first heating process from the heat treatment apparatus 37 into the chamber 61. In operation S14, the vacuum controller 115 controls the pressure reduction apparatus 68 to depressurize the interior of the chamber 61 into which the wafer W is loaded by the wafer transfer apparatus 33 (pressure reduction process). After that, the hydration controller 116 controls the hydration apparatus 69 to supply the moisture-containing gas to the depressurized chamber 61 (hydration process).

Next, the wafer processing system 1 executes operations S15, S16, S17, and S18. In operation S15, the transfer controller 111 controls the wafer transfer apparatus 33 to unload the wafer W after the hydration process from the chamber 61 and transfer the wafer W to the heat treatment apparatus 37. In operation S16, the heat treatment controller 118 controls the heat treatment apparatus 37 to perform the second heating process on the wafer W transferred by the wafer transfer apparatus 33. In operation S17, the transfer controller 111 controls the wafer transfer apparatus 33 to transfer the wafer W after the second heating process from the heat treatment apparatus 37 to the development apparatus 35. In operation S18, the development controller 117 controls the development apparatus 35 to perform the development process on the wafer W transferred by the wafer transfer apparatus 33.

Next, the wafer processing system 1 executes operations S19 and S21. In operation S19, the wafer transfer apparatus 33 transfers the wafer W after the development process from the development apparatus 35. In operation S21, the transfer controller 111 controls the wafer transfer apparatuses 22 and 23 to return the wafer W after the development process transferred by the wafer transfer apparatus 33 to the cassette C. This completes an example of the substrate processing procedure.

### Effect Confirmation Example

The effect of the pressure reduction process and the hydration process was confirmed by forming resist patterns on wafers W using mutually different substrate processing procedures and comparing the line widths. The results are shown below.

### Confirmation Example 1

In each of the following four substrate processing procedures, multiple resist patterns were formed by changing the exposure dose in the exposure process, and the line widths were measured. Procedures 1 and 2 differ in the presence or absence of the pressure reduction process and the hydration process. Procedures 3 and 4 differ in the presence or absence of the pressure reduction process and the hydration process. Procedures 1 and 2, and procedures 3 and 4 differ in the presence or absence of the second heating process.

Procedure 1) Sequentially perform the film formation process, the first heating process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds.

Procedure 2) Sequentially perform the film formation process, the first heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 0 Pa and maintain the post-depressurization pressure for 60 seconds. In the hydration process, supply air into the chamber 61.

Procedure 3) Sequentially perform the film formation process, the first heating process, the second heating process, and the wet-type development process. In the film formation process, form a negative metal-containing resist film with a thickness of 22 nm. In both the first heating process and the second heating process, heat the photosensitive film RF to 180° C. and maintain the photosensitive film RF at 180° C. for 60 seconds.

Procedure 4) Sequentially perform the film formation process, the first heating process, the pressure reduction process, the hydration process, the second heating process, and the wet-type development process. In the film formation process, form a negative metal-containing resist film with a thickness of 22 nm. In both the first heating process and the second heating process, heat the photosensitive film RF to 180° C. and maintain the photosensitive film RF at 180° C. for 60 seconds. In the pressure reduction process, depressurize the interior of the chamber 61 to 0 Pa and maintain the post-depressurization pressure for 60 seconds. In the hydration process, supply air into the chamber 61.

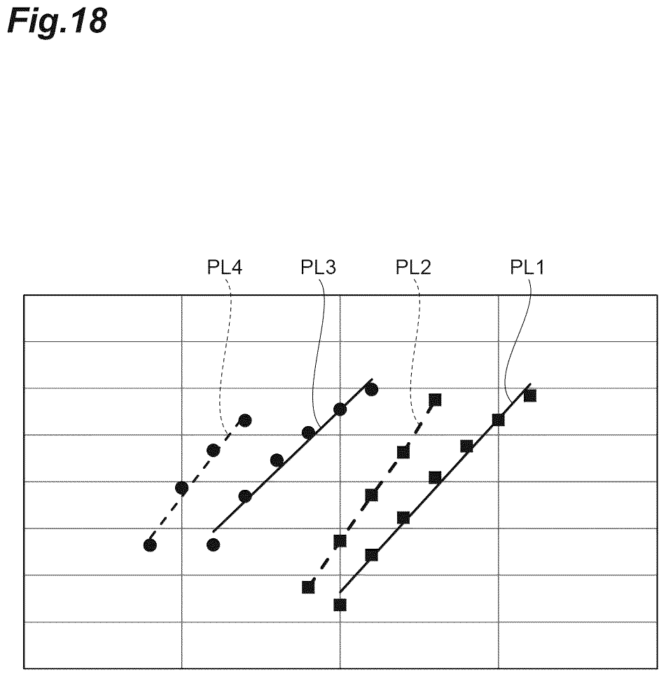

FIG. 18 is a graph illustrating the measurement results of the line widths in each of procedures 1 to 4. The horizontal axis of FIG. 18 represents the exposure dose in the exposure process, and the vertical axis represents the line width. Plot PL1 shows the measurement results of the line widths in procedure 1. Plot PL2 shows the measurement results of the line widths in procedure 2. Plot PL3 shows the measurement results of the line widths in procedure 3. Plot PL4 shows the measurement results of the line widths in procedure 4.

Plot PL2, corresponding to procedure 2, which includes the pressure reduction process and the hydration process, is shifted to the upper left compared to plot PL1, corresponding to procedure 1, which does not include the pressure reduction process and the hydration process. This result indicates that the resistance of the exposed portion to the developer solution is improved by the pressure reduction process and the hydration process.

Similarly, plot PL4, corresponding to procedure 4, which includes the pressure reduction process and the hydration process, is shifted to the upper left compared to plot PL3, corresponding to procedure 3, which does not include the pressure reduction process and the hydration process. This result indicates that the resistance of the exposed portion to the developer solution is improved by the pressure reduction process and the hydration process.

Additionally, plots PL3 and PL4, corresponding to procedures 3 and 4, which include the second heating process, are shifted to the upper left compared to plots PL1 and PL2, corresponding to procedures 1 and 2, which do not include the second heating process. This result indicates that the resistance of the exposed portion to the developer solution is improved by the second heating process.

### Confirmation Example 2

In each of the following six substrate processing procedures, multiple resist patterns were formed by changing the exposure dose in the exposure process, and the line widths were measured. Procedure 11 and procedures 12 to 16 differ in the presence or absence of the pressure reduction process and the hydration process. Procedures 12 to 16 differ in the conditions of the pressure reduction process.

Procedure 11) Sequentially perform the film formation process, the first heating process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds.

Procedure 12) Sequentially perform the film formation process, the first heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 0 Pa and maintain the post-depressurization pressure for 30 seconds. In the hydration process, supply air into the chamber 61.

Procedure 13) Sequentially perform the film formation process, the first heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 0 Pa and maintain the post-depressurization pressure for 120 seconds. In the hydration process, supply air into the chamber 61.

Procedure 14) Sequentially perform the film formation process, the first heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 15 Pa and maintain the post-depressurization pressure for 60 seconds. In the hydration process, supply air into the chamber 61.

Procedure 15) Sequentially perform the film formation process, the first heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 30 seconds. In the hydration process, supply air into the chamber 61.

Procedure 16) Sequentially perform the film formation process, the first heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 120 seconds. In the hydration process, supply air into the chamber 61.

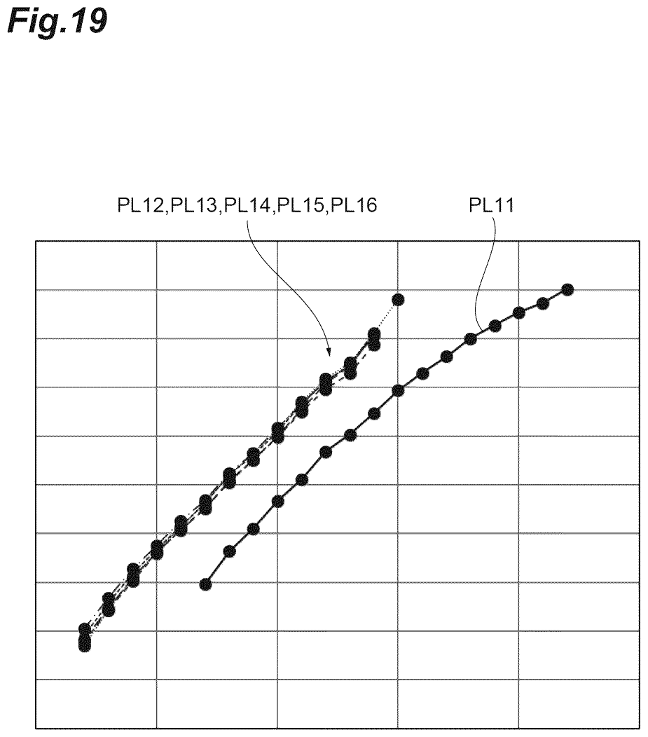

FIG. 19 is a graph illustrating the measurement results of the line widths in each of procedures 11 to 16. The horizontal axis of FIG. 19 represents the exposure dose in the exposure process, and the vertical axis represents the line width. Plot PL11 shows the measurement results of the line widths in procedure 11. Plot PL12 shows the measurement results of the line widths in procedure 12. Plot PL13 shows the measurement results of the line widths in procedure 13. Plot PL14 shows the measurement results of the line widths in procedure 14. Plot PL15 shows the measurement results of the line widths in procedure 15. Plot PL16 shows the measurement results of the line widths in procedure 16.

Plots PL12 to PL16, corresponding to procedures 12 to 16, which include the pressure reduction process and the hydration process, are shifted to the upper left compared to plot PL11, corresponding to procedure 11, which does not include the pressure reduction process and the hydration process. On the other hand, no substantial differences were observed between plots PL12 to PL16. This result indicates that the effect of the pressure reduction process is saturated under conditions where the post-depressurization pressure is 30 Pa or higher and the post-depressurization pressure maintenance time is 30 seconds or less.

### Confirmation Example 3

In each of the following four substrate processing procedures, multiple resist patterns were formed by changing the exposure dose in the exposure process, and the line widths were measured. Procedures 21 and 22 differ in the presence or absence of the pressure reduction process and the hydration process. Procedures 23 and 24 differ in the presence or absence of the pressure reduction process and the hydration process. Procedures 21 and 22, and procedures 23 and 24 differ in the conditions of the second heating process. Furthermore, procedures 24 and 22 differ in the order of the pressure reduction process and the hydration process and the second heating process.

Procedure 21) Sequentially perform the film formation process, the first heating process, the second heating process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 120 seconds.

Procedure 22) Sequentially perform the film formation process, the first heating process, the pressure reduction process, the hydration process, the second heating process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 120 seconds.

Procedure 23) Sequentially perform the film formation process, the first heating process, the second heating process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 90 seconds.

Procedure 24) Sequentially perform the film formation process, the first heating process, the second heating process, the pressure reduction process, the hydration process, and the wet-type development process. In the film formation process, form a negative metal-containing resist film with a thickness of 22 nm. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 90 seconds. In the pressure reduction process, depressurize the interior of the chamber 61 to 30 Pa and maintain the post-depressurization pressure for 60 seconds. In the hydration process, supply air into the chamber 61.

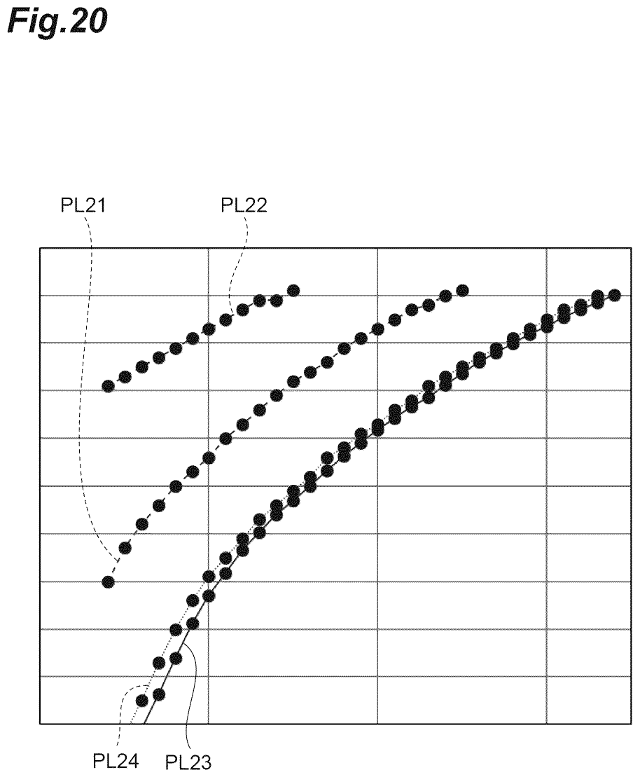

FIG. 20 is a graph illustrating the measurement results of the line widths in each of procedures 21 to 24. The horizontal axis of FIG. 20 represents the exposure dose in the exposure process, and the vertical axis represents the line width. Plot PL21 shows the measurement results of the line widths in procedure 21. Plot PL22 shows the measurement results of the line widths in procedure 22. Plot PL23 shows the measurement results of the line widths in procedure 23. Plot PL24 shows the measurement results of the line widths in procedure 24.

Compared to procedure 21, plot PL23, corresponding to procedure 23 with a shorter second heating process time, is shifted to the lower right compared to plot PL21, corresponding to procedure 21. This result indicates that the resistance of the exposed portion to the developing gas decreased by shortening the second heating process time. No substantial differences were observed between plot PL24, corresponding to procedure 24, which includes the pressure reduction process and the hydration process, and plot PL23, corresponding to procedure 23, which does not include the pressure reduction process and the hydration process. This result indicates that performing the pressure reduction process and the hydration process after the second heating process does not yield the desired effect. It is considered that the polymerized region does not expand when the pressure reduction process and the hydration process are performed after the molecules M1 have polymerized through dehydration condensation.

Plot PL22, corresponding to procedure 22, which performs the pressure reduction process and the hydration process before the second heating process in procedure 21, is shifted to the upper left compared to plot PL21, corresponding to procedure 21. This result indicates that the resistance of the exposed portion to the developing gas was improved by performing the pressure reduction process and the hydration process before the second heating process. It is considered that the unbonded portions of the molecules M1 bond with hydroxyl groups OH through the pressure reduction process and the hydration process, expanding the region that polymerizes during the second heating process.

### Confirmation Example 4

In each of the following five substrate processing procedures, multiple resist patterns were formed by changing the exposure dose in the exposure process, and the line widths were measured. Procedure 31 and procedures 32 to 35 differ in the presence or absence of the pressure reduction process and the hydration process. Procedures 32 to 35 differ in the length of the heating time in the second heating process.

Procedure 31) Sequentially perform the film formation process, the first heating process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 90 seconds.

Procedure 32) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain it at 200° C. for 30 seconds.

Procedure 33) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain it at 200° C. for 60 seconds.

Procedure 34) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 90 seconds.

Procedure 35) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 120 seconds.

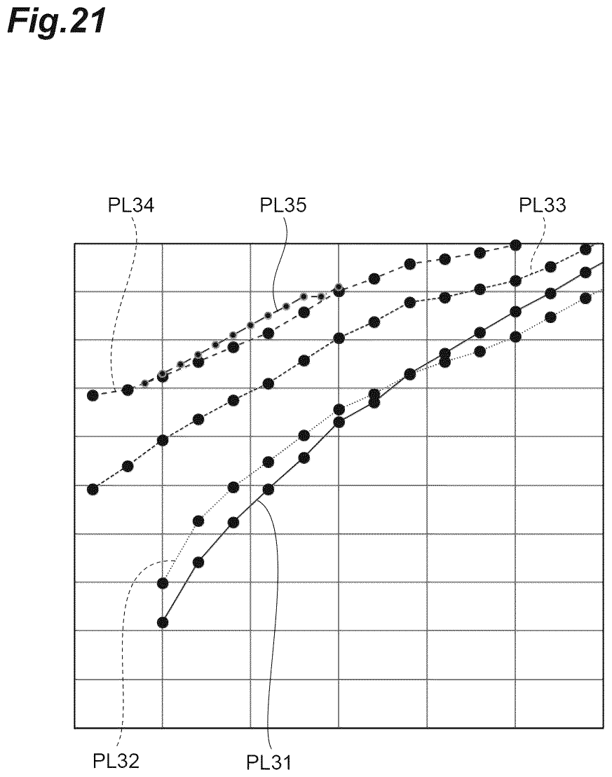

FIG. 21 is a graph illustrating the measurement results of the line widths in each of procedures 31 to 35. The horizontal axis of FIG. 21 represents the exposure dose in the exposure process, and the vertical axis represents the line width. Plot PL31 shows the measurement results of the line widths in procedure 31. Plot PL32 shows the measurement results of the line widths in procedure 32. Plot PL33 shows the measurement results of the line widths in procedure 33. Plot PL34 shows the measurement results of the line widths in procedure 34. Plot PL35 shows the measurement results of the line widths in procedure 35.

Plot PL32, corresponding to procedure 32, which includes the pressure reduction process and the hydration process but has a second heating process time of 30 seconds, almost overlaps with plot PL31, corresponding to procedure 31. This result indicates that the decrease in resistance of the exposed portion to the developing gas when the second heating process time is shortened from 90 seconds to 30 seconds is suppressed by the pressure reduction process and the hydration process. Plot PL33, corresponding to procedure 33 with a second heating process time extended to 60 seconds as compared to procedure 32, is shifted to the upper left compared to plot PL32, compared to procedure 32. Plot PL34, corresponding to procedure 34 with a second heating process time extended to 90 seconds as compared to procedure 33, is shifted further to the upper left compared to plot PL33, corresponding to procedure 33. These results indicate that the resistance of the exposed portion to the developing gas improves as the second heating process time increases.

Plot PL35, corresponding to procedure 35 with a second heating process time extended to 120 seconds as compared to procedure 34, overlaps with plot PL34, corresponding to procedure 34. This result indicates that the improvement in resistance of the exposed portion to the developing gas due to the extension of the second heating process time is saturated at 60 to 90 seconds.

In FIG. 20, it was shown that the resistance of the exposed portion to the developing gas decreases when the second heating process time is shortened from 120 seconds to 90 seconds without the pressure reduction process and the hydration process (see the comparison between plot PL21 and plot PL23). On the other hand, in FIG. 21, it was shown that the resistance of the exposed portion to the developing gas does not decrease when the second heating process time is shortened from 120 seconds to 90 seconds with the pressure reduction process and the hydration process (see the comparison between plot PL34 and plot PL35). This result indicates that the heating time in the second heating process can be shortened by performing the pressure reduction process and the hydration process before the second heating process.

### Confirmation Example 5

In each of the following four substrate processing procedures, multiple resist patterns were formed by changing the exposure dose in the exposure process, and the line widths were measured. Procedure 41 and procedures 42 to 44 differ in the presence or absence of the pressure reduction process and the hydration process. Procedures 42 to 44 differ in the temperature of the first heating process.

Procedure 41) Sequentially perform the film formation process, the first heating process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 90 seconds.

Procedure 42) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 160° C. and maintain the photosensitive film RF at 160° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 90 seconds.

Procedure 43) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 170° C. and maintain the photosensitive film RF at 170° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 90 seconds.

Procedure 44) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 90 seconds.

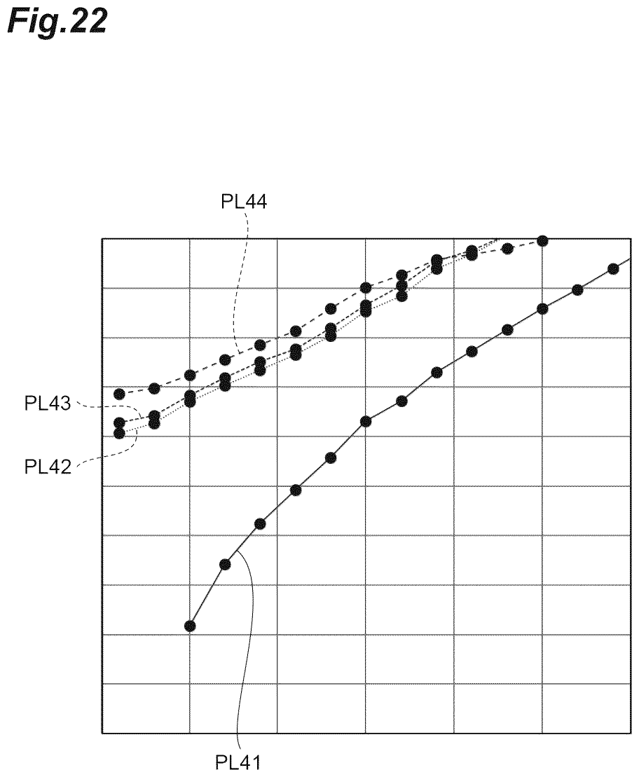

FIG. 22 is a graph illustrating the measurement results of the line widths in each of procedures 41 to 44. The horizontal axis of FIG. 22 represents the exposure dose in the exposure process, and the vertical axis represents the line width. Plot PL41 shows the measurement results of the line widths in procedure 41. Plot PL42 shows the measurement results of the line widths in procedure 42. Plot PL43 shows the measurement results of the line widths in procedure 43. Plot PL44 shows the measurement results of the line widths in procedure 44.

Plots PL42 to PL44, corresponding to procedures 42 to 44, which include the pressure reduction process and the hydration process, are shifted to the upper left compared to plot PL41, corresponding to procedure 41, which does not include the pressure reduction process and the hydration process. Plot PL43, corresponding to procedure 43 with a higher first heating process temperature of 170° C. as compared to procedure 42, is shifted slightly to the upper left compared to plot PL42, corresponding to procedure 42. Plot PL44, corresponding to procedure 44 with a higher first heating process temperature of 180° C. as compared to procedure 43, is shifted slightly to the upper left compared to plot PL43, corresponding to procedure 43. However, the differences between plots PL42 to PL44 are small compared to the difference between plot PL41 and plots PL42 to PL44. This result indicates that the second heating process after the pressure reduction process and the hydration process is more dominant in improving the resistance of the exposed portion to the developing gas than the first heating process before the pressure reduction process and the hydration process.

### Confirmation Example 6

In each of the following four substrate processing procedures, multiple resist patterns were formed by changing the exposure dose in the exposure process, and the line widths were measured. Procedures 51 and 52 differ in the presence or absence of the pressure reduction process and the hydration process. Procedures 51 and 53 differ in the waiting time of the wafer W from the exposure process to the first heating process. Procedures 52 and 54 differ in the order of the pressure reduction process and the hydration process and the first heating process.

Procedure 51) Sequentially perform the film formation process, the first heating process, the second heating process, and the dry method development process. In the film formation process, form a negative metal-containing resist film with a thickness of 22 nm. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 90 seconds.

Procedure 52) Sequentially perform the film formation process, the first heating process, the pressure reduction process, the hydration process, the second heating process, and the dry-type development process. In the film formation process, form a negative metal-containing resist film with a thickness of 22 nm. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 90 seconds.

Procedure 53) Sequentially perform the film formation process, resting of the wafer W, the first heating process, the pressure reduction process, the hydration process, the second heating process, and the dry-type development process. In the film formation process, form a negative metal-containing resist film with a thickness of 22 nm. In resting of the wafer W, expose the photosensitive film RF to air for 48 hours while resting the wafer W. In the first heating process, heat the photosensitive film RF to 180° C. and maintain the photosensitive film RF at 180° C. for 60 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain it at 200° C. for 90 seconds.

Procedure 54) Sequentially perform the film formation process, the pressure reduction process, the hydration process, the first heating process, the second heating process, and the dry-type development process. In the film formation process, form a negative metal-containing resist film with a thickness of 22 nm. In the pressure reduction process, depressurize the interior of the chamber 61 to 30 Pa and maintain the post-depressurization pressure for 60 seconds. In the hydration process, supply air into the chamber 61. In the first heating process, heat the photosensitive film RF to 180° C. and maintain the photosensitive film RF at 180° C. for 60 seconds. In the second heating process, heat the photosensitive film RF to 200° C. and maintain the photosensitive film RF at 200° C. for 90 seconds.

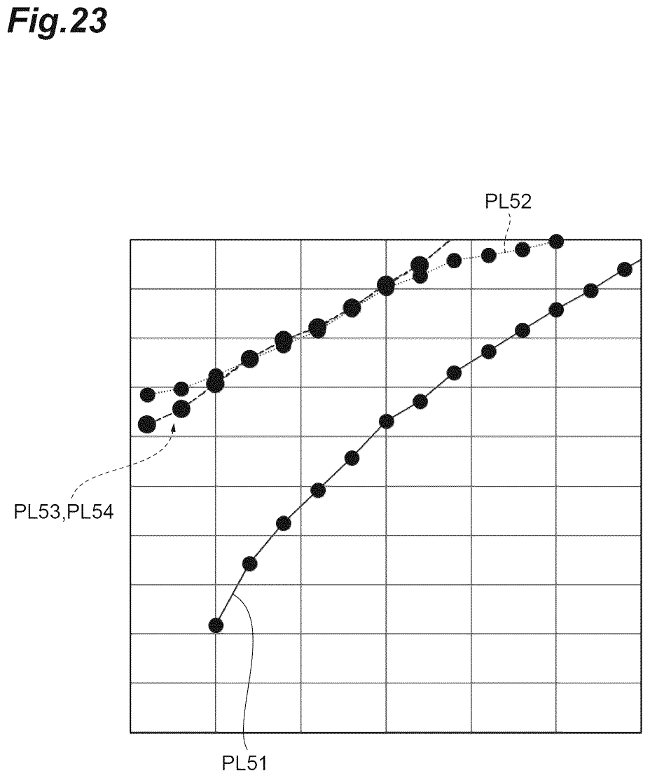

FIG. 23 is a graph illustrating the measurement results of the line widths in each of procedures 51 to 54. The horizontal axis of FIG. 23 represents the exposure dose in the exposure process, and the vertical axis represents the line width. Plot PL51 shows the measurement results of the line widths in procedure 51. Plot PL52 shows the measurement results of the line widths in procedure 52. Plot PL53 shows the measurement results of the line widths in procedure 53. Plot PL54 shows the measurement results of the line widths in procedure 54.

As in other confirmation examples, plots PL52 and PL54, corresponding to procedures 52 and 54, which include the pressure reduction process and the hydration process, are shifted to the upper left compared to plot PL51, corresponding to procedure 51, which does not include the pressure reduction process and the hydration process. No substantial differences were observed between plot PL52 and plot PL54. This result indicates that the order of the pressure reduction process and the hydration process and the first heating process does not affect the resistance of the exposed portion to the developing gas. Plot PL53, corresponding to procedure 53, which includes resting of the wafer W instead of the pressure reduction process and the hydration process, overlaps substantially with plot PL54, corresponding to procedure 54. This result indicates that the saturation of the characteristic changes of the photosensitive film RF when the wafer W is kept at rest in air after the exposure process is accelerated by the pressure reduction process and the hydration process.

### Modification

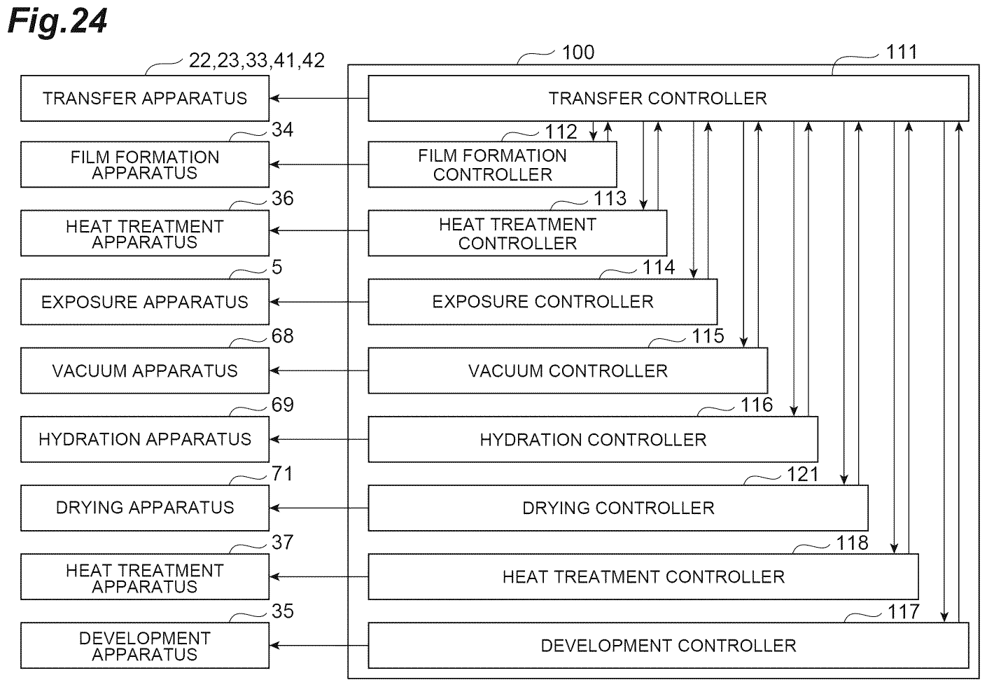

FIG. 24 is a block diagram illustrating a modification of the wafer processing system 1. As illustrated in FIG. 24, the wafer processing system 1 may further include a drying apparatus 71. The drying apparatus 71 dries the environment in which the heat treatment apparatus 37 performs the heating process on the photosensitive film RF compared to the environment in which the hydration apparatus 69 subjects the photosensitive film RF to the moisture-containing gas. Drying means reducing the amount of moisture per unit volume. Drying the environment may be reducing the amount of moisture per unit volume by replacing the gas in the environment with a dry gas or may be reducing the amount of moisture per unit volume by depressurizing the environment. For example, the drying apparatus 71 may be a gas supply apparatus that replaces the gas in the environment where the heat treatment apparatus 37 performs the heating process on the photosensitive film RF with an inert gas (for example, N₂ gas or Ar gas) or dry air. The drying apparatus 71 may be a pressure reduction apparatus that depressurizes the environment where the heat treatment apparatus 37 performs the heating process on the photosensitive film RF to reduce the amount of moisture per unit volume.

The control apparatus 100 may further include a drying controller 121 as a functional block. The drying controller 121 controls the drying apparatus 71 to dry the environment where the heat treatment apparatus 37 performs the heating process on the photosensitive film RF after the hydration apparatus 69 subjects the photosensitive film RF to the moisture-containing gas and before the heat treatment apparatus 37 performs the heating process on the photosensitive film RF.

By drying the environment where the heating process is performed on the photosensitive film RF, the dehydration condensation described above can be promoted. On the other hand, drying the environment where the heating process is performed on the photosensitive film RF makes it difficult for the ligands to be replaced by hydroxyl groups during the heating process. Therefore, if the ligands are not sufficiently replaced by hydroxyl groups before the heating process, the dehydration condensation may be insufficient due to a lack of hydroxyl groups. In contrast, in the wafer processing system 1, the pressure reduction process and the hydration process are performed before the heating process, allowing the ligands to be sufficiently replaced by hydroxyl groups. Thus, the pressure reduction process and the hydration process, combined with the heating process in a dry environment, can further stabilize the degree of dehydration condensation in the photosensitive film RF.

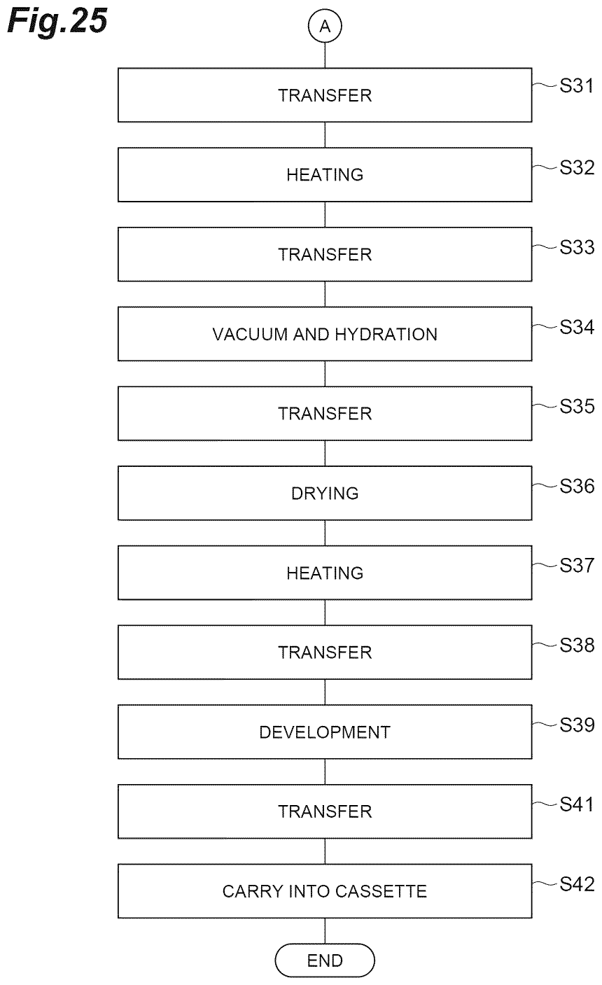

FIG. 25 is a flowchart illustrating a modification of the substrate processing procedure. The substrate processing procedure according to the modification differs from the substrate processing procedure illustrated in FIG. 17 in that the heating process (for example, the second heating process) is performed in an environment drier than the environment in which the hydration process is performed.

For example, as illustrated in FIG. 25, the wafer processing system 1 executes operations S31 to S35, which are similar to operations S11 to S15. Next, the wafer processing system 1 executes operation S36. In operation S36, the drying controller 121 controls the drying apparatus 71 to dry the environment in which the heat treatment apparatus 37 performs the heating process on the photosensitive film RF, compared to the environment in which the hydration apparatus 69 subjects the photosensitive film RF to the moisture-containing gas. Next, the wafer processing system 1 executes operations S37 to S42, which are similar to operations S16 to S21.

### Effect Confirmation Example

In each of the following three substrate processing procedures, multiple resist patterns were formed by changing the exposure dose in the exposure process, and the line widths were measured. Procedures 61 and 62 differ in the presence or absence of the pressure reduction process and the hydration process. Procedures 62 and 63 differ in whether the second heating process is performed in an environment replaced with an inert gas by the drying apparatus 71.

Procedure 61) Sequentially perform the film formation process, the first heating process, the second heating process, and the dry-type development process. In the film formation process, form a negative metal-containing resist film with a thickness of 26 nm. In the first heating process, heat the photosensitive film RF to 180° C. and maintain the photosensitive film RF at 180° C. for 90 seconds. In the second heating process, heat the photosensitive film RF to 200° C. and maintain the photosensitive film RF at 200° C. for 90 seconds.

Procedure 62) Sequentially perform the film formation process, the first heating process, the pressure reduction process, the hydration process, the second heating process, and the dry-type development process. In the film formation process, form a negative metal-containing resist film with a thickness of 26 nm. In the first heating process, heat the photosensitive film RF to 180° C. and maintain the photosensitive film RF at 180° C. for 90 seconds. In the pressure reduction process, depressurize the interior of the chamber 61 to 30 Pa and maintain the post-depressurization pressure for 60 seconds. In the hydration process, supply air into the chamber 61. In the second heating process, heat the photosensitive film RF to 200° C. and maintain the photosensitive film RF at 200° C. for 90 seconds.

Procedure 63) Sequentially perform the film formation process, the first heating process, the pressure reduction process, the hydration process, the second heating process, and the dry-type development process. In the film formation process, form a negative metal-containing resist film with a thickness of 26 nm. In the first heating process, heat the photosensitive film RF to 180° C. and maintain the photosensitive film RF at 180° C. for 90 seconds. In the pressure reduction process, depressurize the interior of the chamber 61 to 30 Pa and maintain the post-depressurization pressure for 60 seconds. In the hydration process, supply air into the chamber 61. In the second heating process, replace the environment in the heat treatment apparatus 37 with N₂ gas and heat the photosensitive film RF to 200° C. and maintain the photosensitive film RF at 200° C. for 90 seconds.

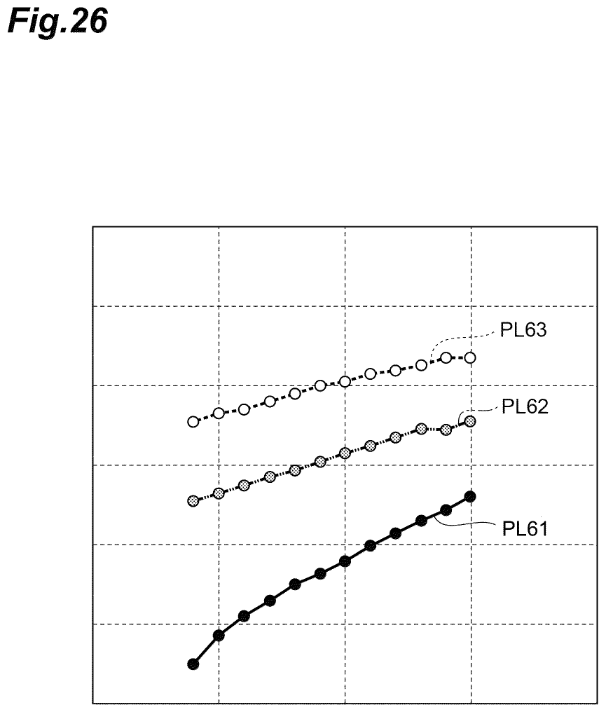

FIG. 26 is a graph illustrating the measurement results of the line widths in each of procedures 61 to 63. The horizontal axis of FIG. 26 represents the exposure dose in the exposure process, and the vertical axis represents the line width. Plot PL61 shows the measurement results of the line widths in procedure 61. Plot PL62 shows the measurement results of the line widths in procedure 62. Plot PL63 shows the measurement results of the line widths in procedure 63.

Plots PL62 and PL63, corresponding to procedures 62 and 63, which include the pressure reduction process and the hydration process, are shifted to the upper left compared to plot PL61, corresponding to procedure 61, which does not include the pressure reduction process and the hydration process. Plot PL63, corresponding to procedure 63, in which replacing with N₂ gas is performed in the second heating process, is shifted further to the upper left compared to plot PL62, corresponding to procedure 62. This result indicates that the degree of dehydration condensation in the photosensitive film RF is further stabilized by the pressure reduction process and the hydration process, combined with the heating process in a dry environment.

### Conclusion

The above disclosures include the following configurations.
(1) A substrate processing method comprising: performing a film formation process of a photosensitive film on a surface of a substrate; accommodating the substrate after the film formation process in a first chamber 51 and performing an exposure process on the photosensitive film in the first chamber 51; accommodating the substrate after the film formation process in a second chamber 61 different from the first chamber 51 and performing a pressure reduction process to depressurize the second chamber 61 to a subatmospheric pressure; after the pressure reduction process and before the development process, performing a hydration process by subjecting the photosensitive film to a moisture-containing gas; and performing a development process on the photosensitive film of the substrate after the exposure process and the hydration process.

As noted in Japanese Unexamined Patent Publication No. 2024-7375, variations in the pattern may occur due to differences in the time from the exposure apparatus to the development apparatus 35. The inventors have found that detachable substances remain in the photosensitive film and affect the pattern after the development process. Hereinafter, these substances remaining in the photosensitive film are referred to as “residual substances.” For example, differences in the period from the exposure apparatus to the heating module may cause differences in the amount of residual substances, leading to pattern variations. Alternatively, differences in the progress of reactions delayed by residual substances may cause pattern variations. In this substrate processing method, the substrate after the film formation process is accommodated in a second chamber 61 different from the first chamber 51 for exposure, and a pressure reduction process is performed to depressurize the second chamber 61, followed by a hydration process. Then, a development process is performed on the photosensitive film of the substrate after the exposure process and the hydration process. The pressure reduction process forcibly reduces the residual substances. The hydration process stabilizes the state of the photosensitive film with reduced residual substances. Therefore, the influence of residual substances between substrates is reduced, suppressing pattern variations between substrates. Additionally, within the photosensitive film on a single substrate, the influence of residual substances depending on the position is reduced, suppressing pattern variations within the substrate. The necessity to match the time from the pressure reduction process to the next process between substrates is reduced, allowing for prioritizing the throughput time of individual substrates and improving the efficiency of substrate processing.
(2) The substrate processing method according to (1), wherein the pressure reduction process is performed after the exposure process. Ligands detached by the exposure process can become residual substances. By performing the pressure reduction process after the exposure process, the variation in the amount of residual substances containing detached ligands can be suppressed, making it further beneficial in suppressing pattern variations.
(3) The substrate processing method according to (2), wherein the exposure process is performed while maintaining the interior of the first chamber 51 at a subatmospheric pressure.

By depressurizing the interior of the first chamber 51, the influence of the exposure process on the photosensitive film can be stabilized. On the other hand, differences in the elapsed time from the exposure timing to the unloading timing from the first chamber 51 may cause variations in the amount of residual substances. The variations in the amount of residual substances caused in this way can be reduced by the pressure reduction process after the exposure process. Therefore, both stabilization of the influence of the exposure process and suppression of variations in the amount of residual substances can be achieved.
(4) The substrate processing method according to (3), wherein the exposure process is performed while the interior of the first chamber 51 is depressurized to a first subatmospheric pressure, and in the pressure reduction process, the interior of the second chamber 61 is depressurized to a second subatmospheric pressure higher than the first subatmospheric pressure.

The cost of the pressure reduction process can be reduced. Additionally, it may take a long time to reach the first subatmospheric pressure. For example, the exposure process may be performed with a degree of vacuum of 1×10⁻⁵ Pa or less. It may take several tens of seconds or more to depressurize from near atmospheric pressure to a degree of vacuum of 1×10⁻⁵ Pa or less. In contrast, by setting the pressure in the pressure reduction process to the second subatmospheric pressure higher than the first subatmospheric pressure, the decrease in processing efficiency due to the pressure reduction process can be suppressed.
(5) The substrate processing method according to any one of (2) to (4), wherein the photosensitive film is a metal-containing resist film. In a negative metal-containing resist film, the influence of residual substances on the pattern tends to be significant. Therefore, the pressure reduction process can further suppress pattern variations.
(6) The substrate processing method according to any one of (2) to (5), wherein in the pressure reduction process, the interior of the second chamber 61 is depressurized to reduce a ligand that has detached due to the exposure process from within the photosensitive film.

The variation in the amount of residual substances containing detached ligands can be further suppressed.
(7) The substrate processing method according to any one of (2) to (6), wherein in the hydration process, the photosensitive film is subjected to the moisture-containing gas so as to substitute a ligand detached in the exposure process with a hydroxyl group.

The stability of the photosensitive film state after the pressure reduction process can be improved, further suppressing pattern variations.
(8) The substrate processing method according to any one of (2) to (7), further comprising performing a heating process on the photosensitive film after the hydration process and before the development process.

By supplementing the exposure process with the heating process, the energy consumption of the exposure process can be reduced. On the other hand, residual substances may also affect the effect of the heating process. By suppressing the variations in the amount of residual substances through the pressure reduction process and further improving the stability of the photosensitive film state through the hydration process, the variations in the effect of the heating process can also be suppressed.
(9) The substrate processing method according to (8), wherein the heating process is performed in an environment drier than the environment in which the hydration process is performed.

By performing the heating process in a dry environment, reactions due to the heating process, such as dehydration condensation, can be promoted.
(10) The substrate processing method according to (8) or (9), wherein in the hydration process, the photosensitive film is subjected to the moisture-containing gas so as to substitute a ligand detached due to the exposure process with a hydroxyl group, and wherein the heating process on the photosensitive film is performed so as to cause a dehydration condensation of molecules in which the ligand is replaced by the hydroxyl group.

By suppressing the variations in the amount of residual substances through the pressure reduction process and further replacing the ligand with the hydroxyl group through the hydration process, variations in the progress of dehydration condensation due to the heating process can be suppressed, further suppressing pattern variations.
(11) The substrate processing method according to any one of (2) to (10), further comprising performing a first heating process on the photosensitive film after the exposure process and before the pressure reduction process, and performing a second heating process on the photosensitive film after the hydration process and before the development process.

By supplementing the exposure process with the second heating process, the energy consumption of the exposure process can be reduced. On the other hand, residual substances may also affect the effect of the second heating process. By performing the pressure reduction process before the second heating process, the variations in the amount of residual substances can be suppressed. Furthermore, by performing the first heating process before the pressure reduction process, the variations in the amount of residual substances can be further suppressed. By suppressing the variations in the amount of residual substances, the variations in the effect of the second heating process can also be suppressed.
(12) The substrate processing method according to (11), wherein the heating process is performed in an environment drier than an environment in which the hydration process is performed.

By performing the heating process in a dry environment, the reactions due to the second heating process, such as dehydration condensation, can be promoted.
(13) The substrate processing method according to (11) or (12), wherein in the first heating process, the substrate is heated to a first temperature, and in the second heating process, the substrate is heated to a second temperature higher than the first temperature.

By sufficiently reducing the amount of residual substances and then heating at a high temperature, thermal energy can be utilized.
(14) The substrate processing method according to any one of (1) to (13), wherein the development process is performed by a wet method in which a developer solution is supplied to the photosensitive film.

By suppressing the variations in the amount of residual substances, variations in solubility to the developer solution can be suppressed.
(15) The substrate processing method according to any one of (1) to (14), wherein the development process is performed by a dry method in which a developing gas is supplied to the photosensitive film.

By suppressing the variations in the amount of residual substances, variations in reactivity to the developing gas can be suppressed.
(16) The substrate processing method according to any one of (1) to (15), wherein in the pressure reduction process, the pressure in the second chamber 61 is maintained for at least a predetermined period at the post-depressurization pressure.

The variations in the amount of residual substances between substrates and within a single substrate can be further suppressed by the pressure reduction process.
(17) A substrate processing apparatus comprising: a chamber 61 isolated from an exposure chamber 51, wherein a substrate is accommodated for an exposure process for a photosensitive film formed on the surface of the substrate; a pressure reduction apparatus 68 configured to depressurize the chamber 61 to a subatmospheric pressure; a hydration apparatus 69 configured to subject the photosensitive film to a moisture-containing gas; a transfer apparatus configured to transfer the substrate; a transfer controller 111 configured to control the transfer apparatus so as to load into and unload from the chamber 61 the substrate after the exposure process for the photosensitive film and before a development process on the photosensitive film; a vacuum controller 115 configured to control the pressure reduction apparatus 68 so as to depressurize an interior of the chamber 61 to the subatmospheric pressure after the substrate is loaded into the chamber 61 and before the substrate is unloaded from the chamber 61; and a hydration controller 116 configured to control the hydration apparatus 69 so as to subject the photosensitive film to the moisture-containing gas after the interior of the chamber 61 is depressurized to the subatmospheric pressure.
(18) A substrate processing system comprising: a film formation apparatus 34 configured to form a photosensitive film on a surface of a substrate; a chamber 61 isolated from an exposure chamber 51 wherein the substrate is accommodated for an exposure process for the photosensitive film; a pressure reduction apparatus 68 configured to depressurize the chamber 61 to a subatmospheric pressure; a hydration apparatus 69 configured to subject the photosensitive film to a moisture-containing gas; a development apparatus 35 configured to perform a development process on the photosensitive film; a transfer apparatus configured to transfer the substrate; a transfer controller 111 configured to control the transfer apparatus so as to load into the chamber 61 the substrate after the exposure process for the photosensitive film and to transfer the substrate unloaded from the chamber 61 to the development apparatus 35; a vacuum controller 115 configured to control the pressure reduction apparatus 68 so as to depressurize the chamber 61 to the subatmospheric pressure after the substrate is loaded into the chamber 61 and before the substrate is unloaded from the chamber 61; and a hydration controller 116 configured to control the hydration apparatus 69 so as to subject the photosensitive film to the moisture-containing gas after the interior of the chamber 61 is depressurized to the subatmospheric pressure and before the substrate is transferred to the development apparatus 35.
(19) The substrate processing system according to (18), further comprising a heat treatment apparatus 37 configured to perform a heating process on the photosensitive film, wherein the transfer controller 111 is configured to control the transfer apparatus so as to transfer the substrate unloaded from the chamber 61 to the heat treatment apparatus 37, and then transfer the substrate from the heat treatment apparatus 37 to the development apparatus 35, and wherein the hydration controller 116 is configured to control the hydration apparatus 69 so as to subject the photosensitive film to the moisture-containing gas after the chamber 61 is depressurized to the subatmospheric pressure and before the substrate is transferred to the heat treatment apparatus 37.
(20) The substrate processing system according to (19), further comprising a drying apparatus 71 configured to dry the environment in which the heat treatment apparatus 37 performs the heating process on the photosensitive film, compared to an environment in which the hydration apparatus 69 subjects the photosensitive film to the moisture-containing gas.
(21) A program for causing an apparatus to execute the substrate processing method according to any one of (1) to (16).

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A substrate processing method comprising:
forming a photosensitive film on a surface of a substrate;
accommodating the substrate with the formed photosensitive film in a first chamber and exposing the photosensitive film to exposure light in the first chamber;
accommodating the substrate with the formed photosensitive film in a second chamber different from the first chamber and performing a pressure reduction process to reduce pressure inside the second chamber to a subatmospheric pressure;
subjecting, after the pressure reduction process, the photosensitive film to a moisture-containing gas; and
developing the photosensitive film of the substrate after said exposing and said subjecting.

2. The substrate processing method according to claim 1, wherein the pressure reduction process is performed after said exposing.

3. The substrate processing method according to claim 2, wherein said exposing is performed while maintaining the first chamber at a subatmospheric pressure.

4. The substrate processing method according to claim 3, wherein said exposing is performed while the first chamber is maintained at a first subatmospheric pressure, and in the pressure reduction process, the pressure inside the second chamber is reduced to a second subatmospheric pressure higher than the first subatmospheric pressure.

5. The substrate processing method according to claim 2, wherein the photosensitive film is a metal-containing resist film.

6. The substrate processing method according to claim 2, wherein in the pressure reduction process, the pressure inside the second chamber is reduced so as to decrease an amount of ligands that has detached due to said exposing within the photosensitive film.

7. The substrate processing method according to claim 2, wherein in said subjecting, the photosensitive film is subjected to the moisture-containing gas so as to substitute a ligand detached due to said exposing with a hydroxyl group.

8. The substrate processing method according to claim 2, further comprising heating the photosensitive film after said subjecting and before said developing.

9. The substrate processing method according to claim 8, wherein said heating is performed in an environment drier than an environment in which said subjecting is performed.

10. The substrate processing method according to claim 8, wherein in said subjecting, the photosensitive film is subjected to the moisture-containing gas so as to substitute a ligand detached due to said exposing with a hydroxyl group, and
wherein said subjecting is performed so as to cause a dehydration condensation of molecules in which the ligand is substituted by the hydroxyl group.

11. The substrate processing method according to claim 2, further comprising:
heating the photosensitive film after said exposing and before the pressure reduction process; and
subsequently heating the photosensitive film after said subjecting and before said developing.

12. The substrate processing method according to claim 11, wherein said subsequently heating is performed in an environment drier than an environment in which said subjecting is performed.

13. The substrate processing method according to claim 11, wherein in said heating, the substrate is heated to a first temperature, and in said subsequently heating, the substrate is heated to a second temperature higher than the first temperature.

14. The substrate processing method according to claim 1, wherein said developing is performed by a wet method in which a developer solution is supplied to the photosensitive film.

15. The substrate processing method according to claim 1, wherein said developing is performed by a dry method in which a developing gas is supplied to the photosensitive film.

16. The substrate processing method according to claim 1, wherein in the pressure reduction process, a pressure in the second chamber is maintained for at the subatmospheric pressure.

17. A substrate processing apparatus comprising:
a chamber isolated from an exposure chamber, wherein a substrate is accommodated in the exposure chamber for an exposure process for a photosensitive film formed on a surface of the substrate;
a pressure reduction apparatus configured to reduce pressure inside the chamber to a subatmospheric pressure;
a hydration apparatus configured to subject the photosensitive film to a moisture-containing gas;
a transfer apparatus configured to transfer the substrate; and
circuitry configured to:
control the transfer apparatus so as to load the substrate into the chamber after the exposure process for the photosensitive film to the exposure light and before a development process on the photosensitive film;
control the pressure reduction apparatus so as to reduce the pressure inside the chamber to the subatmospheric pressure after the substrate is loaded into the chamber and before the substrate is unloaded from the chamber; and
control the hydration apparatus so as to subject the photosensitive film to the moisture-containing gas after the pressure inside the chamber is reduced to the subatmospheric pressure and before the development process on the photosensitive film.

18. A substrate processing system comprising:
the substrate processing apparatus according to claim 17; and
a development apparatus configured to perform the development process,
wherein the circuitry is configured to:
control the transfer apparatus so as to transfer the substrate to the development apparatus after the photosensitive film is subjected to the moisture-containing gas.

19. The substrate processing system according to claim 18, further comprising a heat treatment apparatus configured to heat the photosensitive film,
wherein the circuitry is configured to:
control the transfer apparatus so as to transfer the substrate unloaded from the chamber to the heat treatment apparatus, and then transfer the substrate from the heat treatment apparatus to the development apparatus; and
control the hydration apparatus so as to subject the photosensitive film to the moisture-containing gas after the chamber is depressurized to the subatmospheric pressure and before the substrate is transferred to the heat treatment apparatus.

20. The substrate processing system according to claim 19, further comprising a drying apparatus configured to dry an environment in which the heat treatment apparatus heats the photosensitive film, so as to make the environment drier compared to an environment in which the hydration apparatus subjects the photosensitive film to the moisture-containing gas.

21. A non-transitory memory device having instructions stored thereon that, in response to execution by a processing device, cause the processing device to control a substrate processing apparatus to:
form a photosensitive film on a surface of a substrate;
accommodate the substrate with the formed photosensitive film in a first chamber and expose the photosensitive film to exposure light in the first chamber;
accommodate the substrate with the formed photosensitive film in a second chamber different from the first chamber and perform pressure reduction process to reduce pressure inside the second chamber to a subatmospheric pressure;
subject, after the pressure reduction process, the photosensitive film to a moisture-containing gas; and
develop the photosensitive film of the substrate after exposing the photosensitive film to the exposure light and subjecting the photosensitive film to the moisture-containing gas.
